(19) United States
(12) Patent Application Publication
(10) Pub. No.: US 2025/0380522 A1
(43) Pub. Date: Dec. 11, 2025

(54) IMAGE SENSOR DEVICES AND METHODS OF FORMATION

(71) Applicant: Taiwan Semiconductor Manufacturing Company, Ltd., Hsinchu (TW)

(72) Inventors: Ming-Hsien YANG, Taichung City (TW); Chun-Hao CHOU, Tainan City (TW); Kuo-Cheng LEE, Tainan City (TW)

(21) Appl. No.: 18/734,575

(22) Filed: Jun. 5, 2024

(51) Int. Cl. H01L 27/146; G02F 1/1343; G02F 1/1347; G02F 1/155; G05F 3/26; H04N 19/436

(52) U.S. Cl. CPC H10F 39/806; G02F 1/13439; G02F 1/13473; G02F 1/155; H10F 39/024; H10F 39/182; H10F 39/8053; H10F 39/8063; H10F 39/807; G05F 3/262; H04N 19/436

(57) ABSTRACT

An image sensor device includes a pixel sensor array and an electrochromic layer stack over the pixel sensor array. An electrical input may be applied to the electrochromic layer stack to adjust the intensity of incident light received at the pixel sensors of the pixel sensor array. In this way, the electrochromic layer stack enables the intensity of incident light received at the pixel sensors of the pixel sensor array to be adjusted to a suitable level for the level of illuminance in the surrounding environment, and enables the intensity of incident light received at the pixel sensors of the pixel sensor array to be adapted to changes in the level of illuminance in the surrounding environment.

### BACKGROUND

Complementary metal oxide semiconductor (CMOS) image sensors utilize light-sensitive CMOS circuitry to convert light energy (e.g., photons) into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a transfer gate, which is used to sample the charge of the photodiode. Colors may be determined by placing filters over the light-sensitive CMOS circuitry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a portion of an image sensor device described herein.

FIGS. 2A-2H are diagrams of example implementations of a portion of a pixel sensor array described herein.

FIG. 3 is a diagram of an example implementation of tuning optical transmittance of an electrochromic layer stack based on the level of illuminance in the surrounding environment.

FIGS. 4A-4L are diagrams of an example implementation of forming an image sensor device described herein.

FIGS. 5A-5C are diagrams of example image sensor devices described herein.

FIGS. 6A-6H are diagrams of example implementations of a portion of a pixel sensor array described herein.

FIGS. 7A-7C are diagrams of an example implementation of adjusting an optical transmittance of an electrochromic layer stack described herein.

FIGS. 8A-8C are diagrams of an example implementation of a current mirror circuit or a portion thereof described herein.

FIGS. 9A and 9B are diagrams of an example implementation of a compression circuit and a decompression circuit that may be communicatively coupled to one or more pixel sensor arrays described herein.

FIG. 10 is a flowchart of an example process associated with forming an image sensor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary metal oxide semiconductor (CMOS) image sensor devices have a broad spectrum of use cases, including digital cameras, security cameras, night vision, and/or automotive sensing, among other examples. In some use cases, a CMOS image sensor device can be exposed to changing environments that have different levels of illuminance. For example, in an automotive sensing use case, a CMOS image sensor device may experience constantly changing levels of illuminance as an automobile in which the CMOS image sensor device is included moves between environments having different levels of illuminance. This can occur, for example, where the automobile transitions between a tunnel and an open environment or where the automobile passes under a bridge, among other examples. Changing levels of illuminance can pose challenges to the CMOS image sensor device to optimize the exposure intensity of incident light received at the CMOS image sensor device. For example, transitioning from an environment with a low level of illuminance to an environment with a high level of illuminance may result in overexposure of the CMOS image sensor device to incident light, which may cause loss of detail in images and/or video generated by the CMOS image sensor device due to saturation of the pixel sensors of the CMOS image sensor device. As another example, transitioning from an environment with a high level of illuminance to an environment with a low level of illuminance may result in underexposure of the CMOS image sensor device to incident light, which may also cause loss of detail in images and/or video generated by the CMOS image sensor device due to the images and/or video being too dark.

In some implementations described herein, a CMOS image sensor device includes a pixel sensor array and an electrochromic layer stack over the pixel sensor array. An electrical input may be applied to the electrochromic layer stack to adjust the intensity of incident light received at the pixel sensors of the pixel sensor array. In this way, the electrochromic layer stack enables the intensity of incident light received at the pixel sensors of the pixel sensor array to be adjusted to a suitable level for the level of illuminance in the surrounding environment, and enables the intensity of incident light received at the pixel sensors of the pixel sensor array to be adapted to changes in the level of illuminance in the surrounding environment.

Moreover, the pixel sensor array may include a monochromatic pixel sensor array configured to sense a single wavelength range of visible light (e.g., a red pixel sensor array, a blue pixel sensor array), which enables the CMOS image sensor device to be used for high dynamic range (HDR) automotive use cases and/or other uses that involve machine reading of objects of a particular color. The monochromatic pixel sensor array may be accompanied by a full-range visible light pixel sensor array (e.g., a red-green-blue (RGB) pixel sensor array) that may generate full-color images and/or video for comparison to and verification of the machine reading outcomes based on the monochromatic images and/or video generated by the monochromatic pixel sensor array.

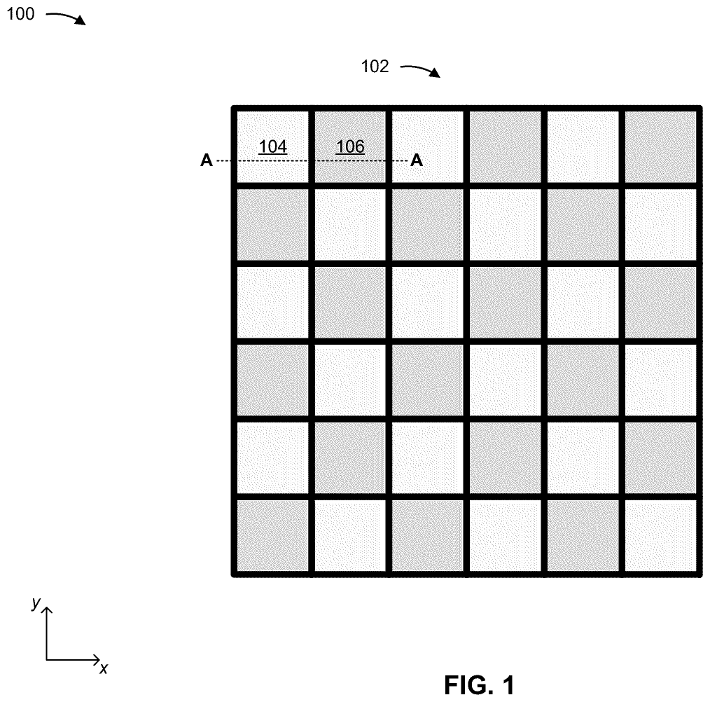

FIG. 1 is a diagram of an example of a portion of an image sensor device 100 described herein. The portion of the image sensor device 100 illustrated in FIG. 1 includes a pixel sensor array 102. The pixel sensor array 102 may include a monochromatic pixel sensor array configured for monochromatic sensing and/or machine reading (e.g., reading of road signs, readings of markings on vehicles). FIG. 1 illustrates a top view of the pixel sensor array 102.

As shown in FIG. 1, the pixel sensor array 102 includes a plurality of pixel sensors, including white pixel sensors (or “clear” pixel sensors) 104 and color pixel sensors 106. The white pixel sensors 104 and the color pixel sensors 106 may be arranged in a grid in an x-y plane (e.g., a lateral or horizontal plane) the pixel sensor array 102. For example, the white pixel sensors 104 and the color pixel sensors 106 may be arranged in an alternating manner in a plurality of rows in the x-direction in the image sensor device 100, and may be arranged in an alternating manner in a plurality of columns in the y-direction in the image sensor device 100. However, other arrangements for the white pixel sensors 104 and the color pixel sensors 106 in the pixel sensor array 102 are within the scope of the present disclosure.

In some implementations, the white pixel sensors 104 and/or the color pixel sensors 106 are square-shaped (as shown in the example in FIG. 1). In some implementations, the white pixel sensors 104 and/or the color pixel sensors 106 include other shapes such as rectangle shapes, circle shapes, octagon shapes, diamond shapes, and/or other shapes.

A white pixel sensor 104 (or a “clear” pixel sensor) refers to a non-discriminating or non-filtering pixel sensor that is configured to sense incident light across the entire visible light spectrum. A white pixel sensor 104 may be used for the general detection of objects in the field of view of the pixel sensor array 102, such as trucks, pedestrians, obstacles, and/or backgrounds, among other examples.

A color pixel sensor 106 refers to a pixel sensor that senses only a portion of the visible light spectrum of incident light. In particular, a color pixel sensor 106 may be configured to sense a particular wavelength range of incident light associated with a particular color of visible light. Therefore, the pixel sensor array 102 may be referred to as a monochromatic pixel sensor array. For example, the color pixel sensors 106 may be configured to sense a same wavelength range associated with a red component of incident light, and may therefore be referred to as red pixel sensors. As another example, the color pixel sensors 106 may be configured to sense a same wavelength range associated with a blue component of incident light, and may therefore be referred to as blue pixel sensors. As another example, the color pixel sensors 106 may be configured to sense a same wavelength range associated with a green component of incident light, and may therefore be referred to as green pixel sensors. The color pixel sensors 106 may be used for detecting particular types of objects in the field of view of the pixel sensor array 102, such as vehicle lights, traffic lights, road signs, and/or vehicles of a particular color, among other examples.

As indicated above, FIG. 1 is provided as an example. Other examples may differ from what is described with regard to FIG. 1.

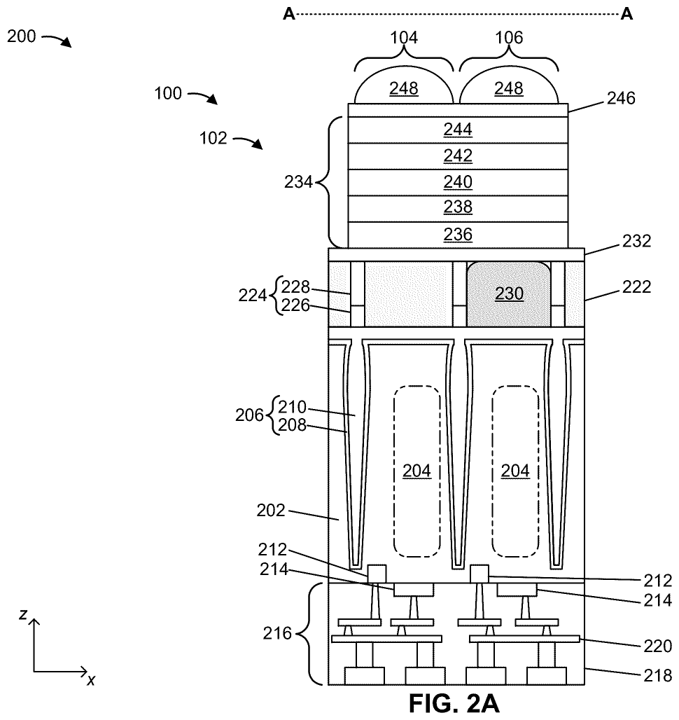

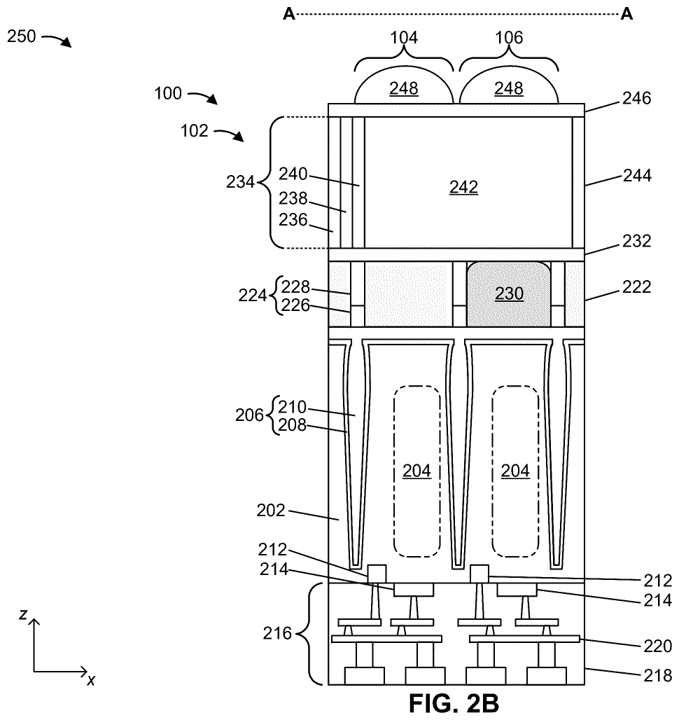

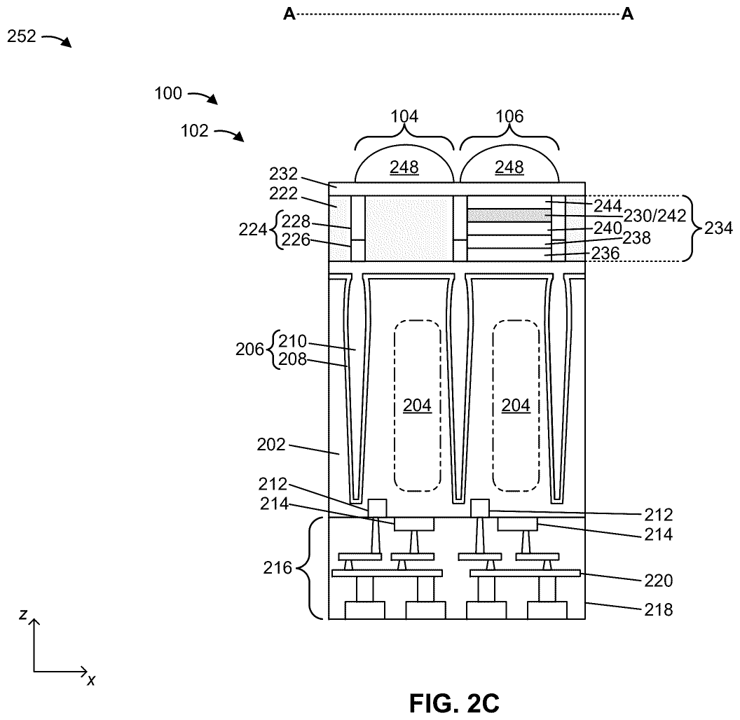

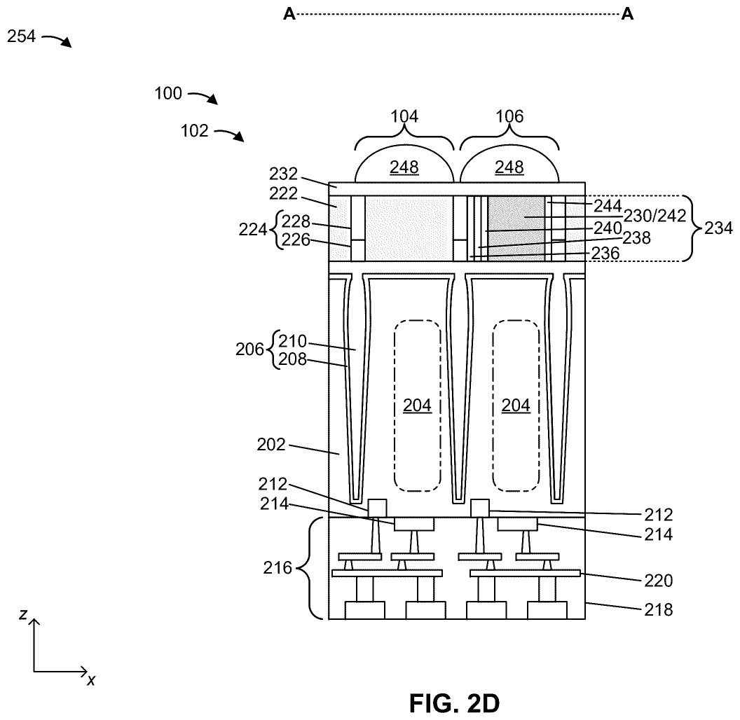

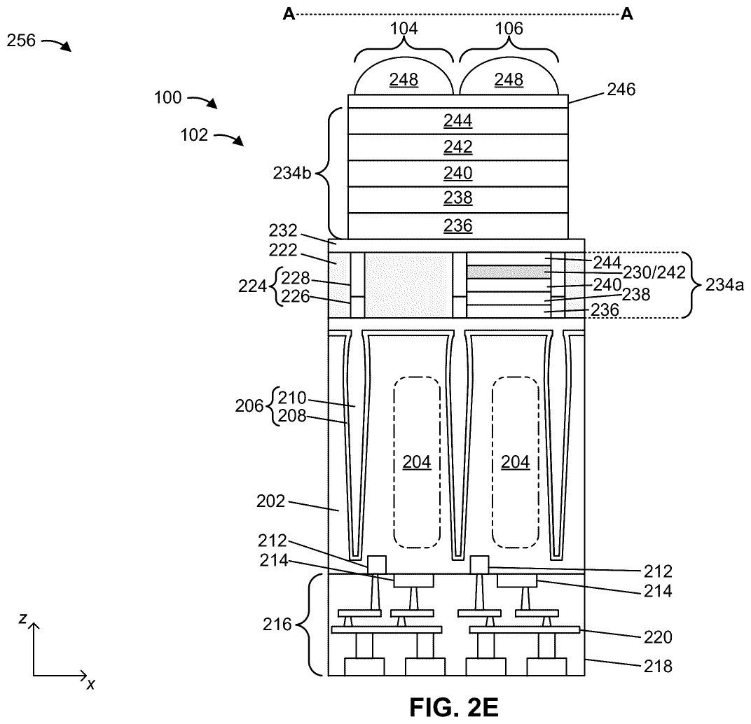

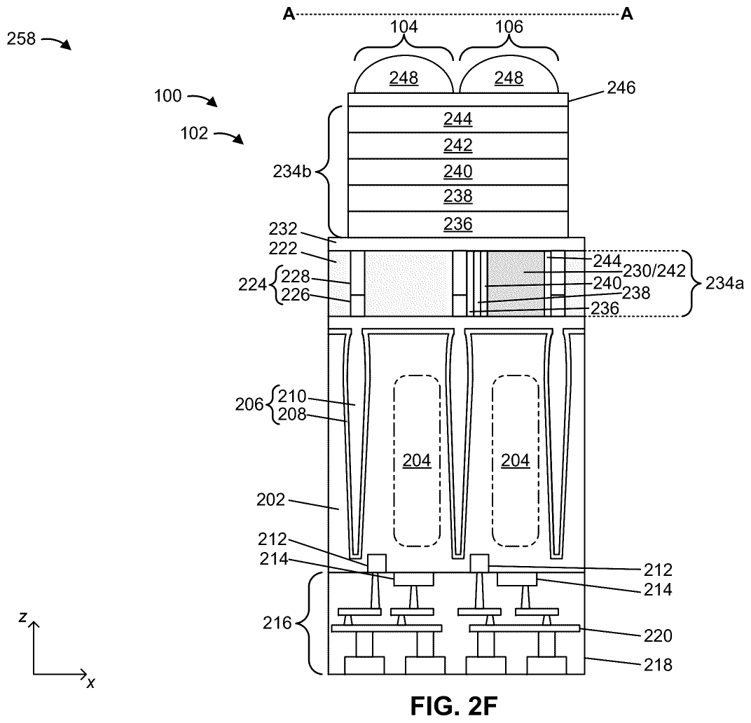

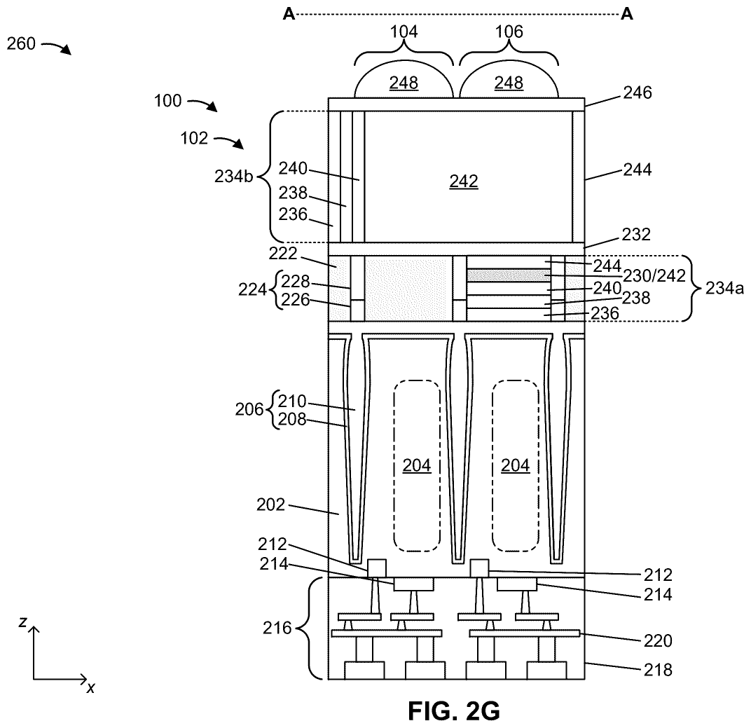

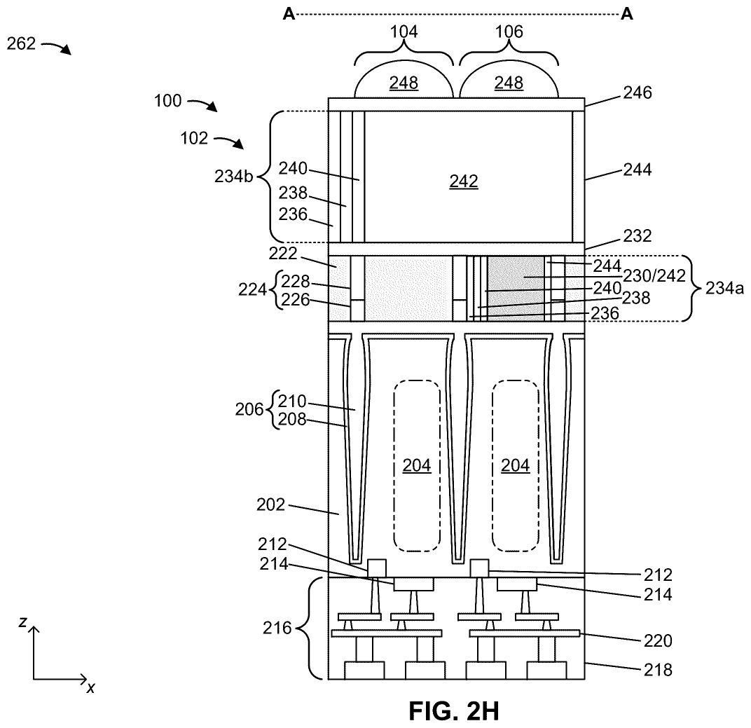

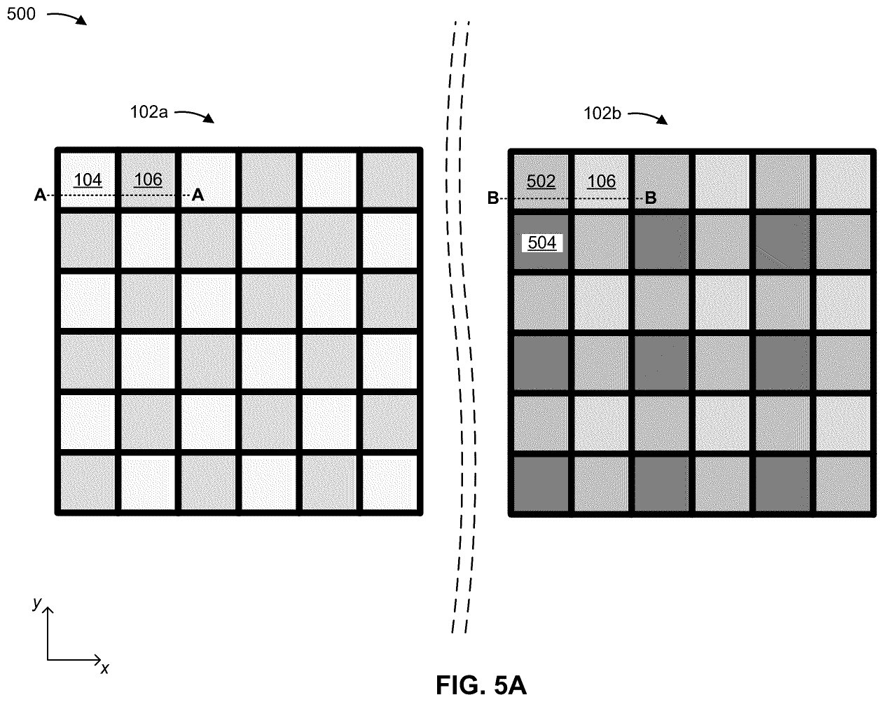

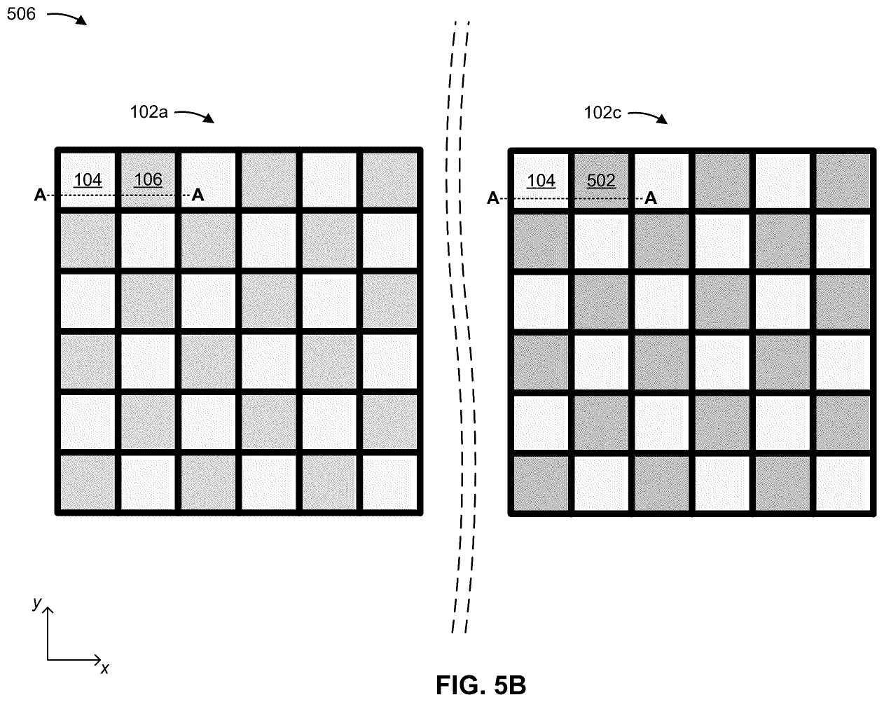

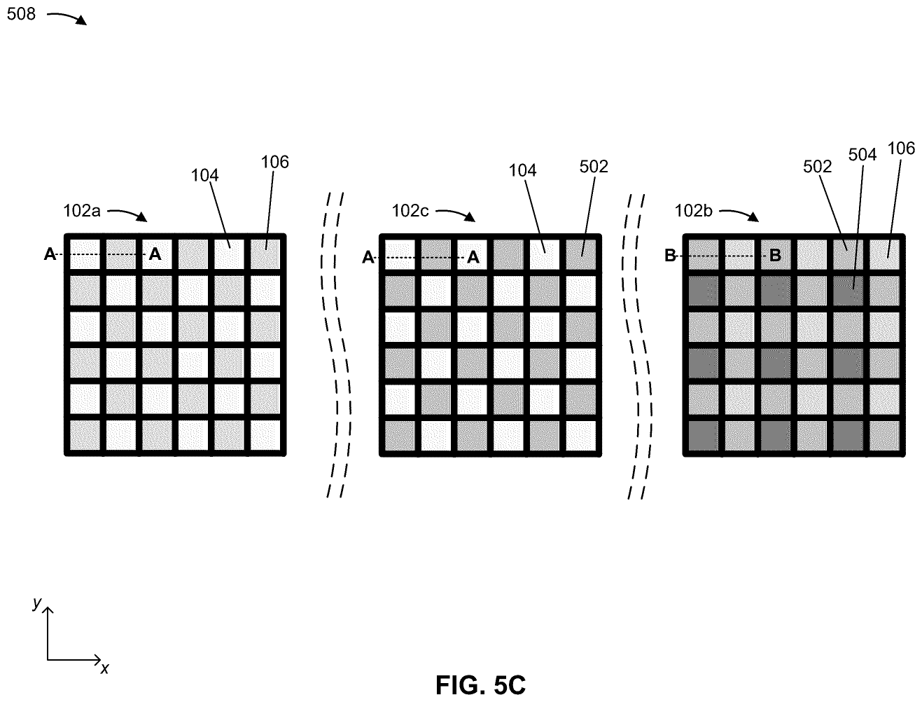

FIGS. 2A-2H are diagrams of example implementations of a portion of a pixel sensor array described herein. For example, each of FIGS. 2A-2H illustrates a cross-sectional view of an example implementation of a portion of the pixel sensor array 102 of the image sensor device 100. However, the example implementations of the portion of the pixel sensor array 102 illustrated in FIGS. 2A-2H may be used in other monochromatic pixel sensor arrays described herein, such as those illustrated and described in connection with FIGS. 5A-5C and/or 6A-6H, among other examples. The cross-sectional views illustrated in FIGS. 2A-2H are along the line A-A in FIG. 1.

The example implementations of the portion of the pixel sensor array 102 of the image sensor device 100 illustrates in FIGS. 2A-2H each include one or more electrochromic layer stacks. An electrochromic layer stack may be included above the color pixel sensors 106 in the pixel sensor array 102 (and, in some implementations, also above the white pixel sensors 104 in the pixel sensor array 102) to enable the intensity of incident light sensed by the color pixel sensors 106 to be adjusted and/or dynamically tuned, for example, based on the level of illuminance in the environment of the image sensor device 100. An electrochromic layer stack described herein includes an electrochromic layer having a transmittance that can be modified by applying an electrical input across the electrochromic layer. Thus, depending on the magnitude of the electrical input (or polarity of the electrical input), the electrochromic layer can be biased to achieve a greater transmittance or a lesser transmittance for the electrochromic layer, thereby enabling the intensity of incident light sensed by the color pixel sensors 106 to be adjusted and/or dynamically tuned.

Turning to FIG. 2A, an example implementation 200 of a portion of the pixel sensor array 102 of the image sensor device 100 includes a white pixel sensor 104 and an adjacent color pixel sensor 106. As shown in FIG. 2A, the image sensor device 100 may include a substrate 202. The substrate 202 may include a semiconductor layer, a semiconductor die substrate, a semiconductor wafer, a stacked semiconductor wafer, or another type of substrate in which semiconductor pixels may be formed. In some implementations, the substrate 202 is formed of silicon (Si) (e.g., a silicon substrate), a material including silicon, a III-V compound semiconductor material such as gallium arsenide (GaAs), a silicon on insulator (SOI), or another type of semiconductor material that is capable of generating a charge from photons of incident light. In some implementations, the substrate 202 is formed of a doped material (e.g., a p-doped material or an n-doped material), such as a doped silicon.

Each of the white pixel sensor 104 and the color pixel sensor 106 may include a photodiode 204 that is included in the substrate 202. The photodiodes 204 may include a plurality of regions of the substrate 202 that are doped with various types of ions to form a p-n junction or a PIN junction (e.g., a junction between a p-type portion, an intrinsic (or undoped) type portion, and an n-type portion). For example, the substrate 202 may be doped with an n-type dopant to form one or more n-type regions of a photodiode 204, and the substrate 202 may be doped with a p-type dopant to form a p-type region of the photodiode 204. A photodiode 204 may be configured to absorb photons of incident light that enter the substrate 202. The absorption of photons causes the photodiode 204 to accumulate a charge (referred to as a photocurrent) due to the photoelectric effect. Photons may bombard the photodiode 204, which causes emission of electrons in the photodiode 204.

An isolation structure 206 may be included around the photodiodes 204 of the white pixel sensors 104 and the color pixel sensors 106 of the pixel sensor array 102. The isolation structure 206 may be a deep trench isolation (DTI) structure that includes a plurality of interconnected elongated trenches that extend downward into the substrate 202. The elongated trenches may extend into the substrate 202 from a backside surface of the substrate 202 opposing the frontside surface. The pixel sensor array 102 may be referred to as a backside illuminated (BSI) pixel sensor array in that photons enter the photodiodes 204 from the backside surface of the substrate 202. Thus, the isolation structure 206 may be referred to as a backside DTI (BDTI) structure. Alternatively, the isolation structure 206 may include a frontside DTI (FDTI) structure that extends into the substrate from the front surface of the substrate 202.

The isolation structure 206 may include one or more layers. The one or more layers may include a liner 208 and a fill layer 210, among other examples. A portion of the liner 208 and/or a portion of the fill layer 210 may extend along the backside surface of the substrate 202. Alternatively, the liner 208 and/or the fill layer 210 may be omitted form the backside surface of the substrate 202.

The fill layer 210 may confine incident light around a photodiode 204 of an associated pixel sensor (e.g., an associated white pixel sensor 104, an associated color pixel sensor 106) to increase the quantum efficiency of the pixel sensor and/or to reduce optical crosstalk between adjacent pixel sensors in the pixel sensor array 102. In some implementations, the fill layer 210 includes one or more dielectric materials, such as a silicon oxide (SiOₓ), a silicon nitride (SiₓN_{y}), a silicon carbide (SiCₓ), a silicon carbon nitride (SiCN), and/or a silicon oxynitride (SiON), among other examples. The liner 208 may include a silicon nitride (SiₓN_{y}), a silicon carbide (SiCₓ), an aluminum oxide (AlₓO_{y} such as Al₂O₃), a tantalum oxide (TaₓO_{y} such as Ta₂O₅), a hafnium oxide (HfOₓ such as HfO₂) and/or another high dielectric constant (high-k) dielectric material.

The photocurrent generated by a photodiode 204 (e.g., a photodiode 204 of the white pixel sensor 104, a photodiode 204 of the color pixel sensor 106) may be transferred and/or stored in an associated floating diffusion (FD) node 212 in the substrate 202. An FD node 212 may include a doped portion (e.g., an n-doped portion, a p-doped portion) of the substrate 202 that is configured to accumulate and store a photocurrent.

Each of the white pixel sensor 104 and the color pixel sensor 106 may include a transfer gate 214. A transfer gate 214 may be located at a frontside surface of the substrate 202. A transfer gate 214 may be configured to transfer the photocurrent generated by a photodiode 204 to an FD node 212. For example, the transfer gate 214 of the white pixel sensor 104 may be configured to transfer the photocurrent generated by the photodiode 204 of the white pixel sensor 104 to the FD node 212 of the white pixel sensor 104. As another example, the transfer gate 214 of the color pixel sensor 106 may be configured to transfer the photocurrent generated by the photodiode 204 of the color pixel sensor 106 to the FD node 212 of the color pixel sensor 106. A transfer gate 214 may be implemented by a field effect transistor (FET), such as a planar FET, a finFET, a nanostructure FET (e.g., a gate all around (GAA) FET, a nanowire FET, a nanosheet FET, a multi-bridge channel FET, a nanoribbon FET), and/or another type of FET.

An interconnect layer 216 (e.g., a back end of line (BEOL) region or backend region) may be included on the frontside of the substrate 202. The interconnect layer 216 may include one or more dielectric layers 218 and one or more metallization layers 220 included in the one or more dielectric layers 218. One or more of the metallization layers 220 may be electrically connected with portions of the pixel sensor array 102, including the FD nodes 212 and/or the transfer gates 214. The one or more dielectric layers 218 may include a silicon oxide (SiOₓ), a silicon nitride (SiₓN_{y}), a silicon carbide (SiCₓ), or a mixture thereof, such as a silicon carbon nitride (SiCN), or a silicon oxynitride (SiON), among other examples. The one or more metallization layers 220 may include contacts, trenches, vias, interconnects, columns, pillars, single damascene structures, and/or dual damascene structures, among other examples. The one or more metallization layers 220 may include tungsten (W), cobalt (Co), titanium (Ti), copper (Cu), gold (Au), silver (Ag), molybdenum (Mo), ruthenium (Ru), a metal alloy, and/or another type of electrically conductive material, among other examples.

On the backside of the substrate 202, a buffer layer 222 may be included, and another isolation grid 224 may be included in the buffer layer 222. The buffer layer 222 may include one or more dielectric materials, such as a silicon oxide (SiOₓ), a silicon nitride (SiₓN_{y}), a silicon carbide (SiCₓ), a silicon carbon nitride (SiCN), and/or a silicon oxynitride (SiON), among other examples. The isolation grid 224 may include an isolation structure (e.g., a grid structure or grid isolation structure) above the isolation structure 206. The isolation grid 224 may include a plurality of interconnected structures formed from one or more layers that are etched to form the interconnected structures. In a top view of the isolation grid 224, the isolation grid 224 has a grid-shaped configuration similar to the isolation structure 206. The isolation grid 224 may be configured to provide increased optical crosstalk reduction for the pixel sensor array 102, in combination with the isolation structure 206.

The isolation grid 224 may include an oxide grid, a dielectric grid, a color filter in a box (CIAB) grid, and/or a composite metal grid (CMG), among other examples. In some implementations, the isolation grid 224 includes a metal layer 226 and a dielectric layer 228 over and/or on the metal layer 226. The metal layer 226 may include tungsten (W), cobalt (Co), and/or another type of metal or metal-containing material. The dielectric layer 228 may include an organic material, an oxide, a nitride, and/or another type of dielectric material such as a silicon oxide (SiOₓ) (e.g., silicon dioxide (SiO₂)), a hafnium oxide (HfOₓ), a hafnium silicon oxide (HfSiOₓ), an aluminum oxide (AlₓO_{y}), a silicon nitride (SiₓN_{y}), a zirconium oxide (ZrOₓ), a magnesium oxide (MgOₓ), a yttrium oxide (YₓO_{y}), a tantalum oxide (TaₓO_{y}), a titanium oxide (TiOₓ), a lanthanum oxide (LaₓO_{y}), a barium oxide (BaOₓ), a silicon carbide (SiC), a lanthanum aluminum oxide (LaAlOₓ), a strontium oxide (SrO), a zirconium silicon oxide (ZrSiOₓ), and/or a calcium oxide (CaO), among other examples.

A color filter 230 may be included in the areas between the columns of the isolation grid 224. In particular, the color filter 230 may be included in between columns of the isolation grid 224 over the photodiodes 204 of the color pixel sensors 106. The color filter 230 for a color pixel sensor 106 may be configured to filter incident light to allow a particular wavelength of the incident light to pass to the photodiode 204 of the color pixel sensor 106. As indicated above in connection with FIG. 1, the pixel sensor array 102 may be a monochromatic pixel sensor array. Accordingly, the color pixel sensors 106 in the pixel sensor array 102 may all include the same type of color filter 230. For example, the color pixel sensors 106 of the pixel sensor array 102 may each include a color filter 230 that is configured filter incident light to allow a particular wavelength of the incident light associated with red visible light to pass to the photodiodes 204 of the color pixel sensors 106. As another example, the color pixel sensors 106 of the pixel sensor array 102 may each include a color filter 230 that is configured filter incident light to allow a particular wavelength of the incident light associated with green visible light to pass to the photodiodes 204 of the color pixel sensors 106. As another example, the color pixel sensors 106 of the pixel sensor array 102 may each include a color filter 230 that is configured filter incident light to allow a particular wavelength of the incident light associated with blue visible light to pass to the photodiodes 204 of the color pixel sensors 106.

Another buffer layer 232 may be included over and/or on buffer layer 222, and over and/or on the color filters 230. The buffer layer 232 may include an approximately flat layer that provides an approximately flat dielectric substrate on which an electrochromic layer stack 234 may be formed. The electrochromic layer stack 234 may be formed over the pixel sensors of the pixel sensor array 102, including over the white pixel sensors 104 and the color pixel sensors 106. As indicated above, the electrochromic layer stack 234 may be included to enable the intensity of incident light sensed by the white pixel sensors 104 and the color pixel sensors 106 to be adjusted and/or dynamically tuned based on the level of illuminance in the environment of the image sensor device 100.

The electrochromic layer stack 234 may include a bottom transparent electrode 236, an ion-storage layer 238 above and/or on the bottom transparent electrode 236, an electrolyte layer 240 above and/or on the ion-storage layer 238, an electrochromic layer 242 above and/or on the electrolyte layer 240, and a top transparent electrode 244 above and/or on the electrochromic layer 242. In the example implementation 200, the layers of the electrochromic layer stack 234 may be formed as thin films that are stacked in the z-direction (e.g., that are vertically stacked) in the image sensor device 100.

The bottom transparent electrode 236 and the top transparent electrode 244 may each include one or more transparent or semi-transparent electrically conductive materials. Examples of such materials include indium tin oxide (ITO), fluorine-doped tin dioxide (FTO), and/or ITO-coated polyethylene glycol terephthalate (PET-ITO), among other examples. The bottom transparent electrode 236 and the top transparent electrode 244 enable an electrical input to be applied across the electrochromic layer stack 234 to modify the optical transmittance of the electrochromic layer stack 234.

The ion-storage layer 238 is included to trap and store ions that may migrate toward or away from the electrochromic layer 242. Thus, the ion-storage layer 238 may include one or more materials having a high ion storage capacity, such as a metal oxide (e.g., nickel oxide (NiO)) or a conductive polymer, among other examples. The ion-storage layer 238 may retain ions in the absence of an electrical input applied to the electrochromic layer stack 234, thereby enabling the electrochromic layer 242 to be configured in a persistent optical transmittance state.

The electrolyte layer 240 is included to facilitate ion migration between the ion-storage layer 238 and the electrochromic layer 242. Thus, the electrolyte layer 240 may be referred to as an ion-conducting layer or an ion-transport layer. The electrolyte layer 240 may include one or more ion-conducting materials, including a film that is doped with an electrolyte (e.g., a lithium salt, an ammonium salt), a polymer having ionic conductivity, and/or another suitable ion-conducting material.

The electrochromic layer 242 may include a transition metal oxide, a transition metal, a conductive polymer, a viologen, a lanthanoid, a metal phthanlocyanine, and/or another suitable material that can be reversibly oxidized to modify the optical transmittance of the electrochromic layer 242. The electrochromic layer 242 may be reversibly oxidized (e.g., based on an electrical input applied to the bottom transparent electrode 236 and the top transparent electrode 244) through the capture and release of ions (e.g., ions from the ion-storage layer 238). Such materials may include a tungsten oxide (WOₓ such as WO₃ or WO₆), molybdenum oxide (MoOₓ such as MoO₃), vanadium oxide (VₓO_{y} such as V₂O₅), titanium oxide (TiOₓ such as TiO₂), niobium oxide (NbₓO_{y} such as Nb₂O₅), nickel oxide (NiO), tin oxide (SnO), iron oxide (FeₓO_{y} such as (Fe₂O₃)), cobalt oxide (CoO), iridium hydroxide (Ir(OH)₃), Poly(3,4-ethylenedioxythiophene) (PDOT), polypyrrole (PPy), poly(thiophene)s, (PT), polyaniline (PANI), 3-aryl-4,5-bis (pyridine-4-yl) isoxazole derivatives, a metal, an alloy, a hydride, a chalcogenide and/or a telluride that includes a metal such as manganese (Mn), magnesium (Mg), cobalt (Co), copper (Cu), nickel (Ni), zinc (Zn), vanadium (V), chromium (Cr), iron (Fe), bismuth (Bi), antimony (Sb), gold (Au), platinum (Pt), titanium (Ti), and/or niobium (Nb), among another examples.

Another buffer layer 246 may be included on the electrochromic layer stack 234, and micro-lenses 248 may be included above the buffer layer 246. In some implementations, each of the white pixel sensors 104 and each of the color pixel sensors 106 include a micro-lens 248. In some implementations, two or more white pixel sensors 104 share a micro-lens 248, two or more color pixel sensors 106 share a micro-lens 248, and/or a white pixel sensor 104 and a color pixel sensor 106 share a micro-lens 248. The micro-lenses 248 may be formed to focus incident light toward the photodiodes 204 of the white pixel sensors 104 and the color pixel sensors 106.

FIG. 2B illustrates another example implementation 250 of a portion of the pixel sensor array 102 of the image sensor device 100 that includes a white pixel sensor 104 and an adjacent color pixel sensor 106. As shown in FIG. 2B, the example implementation 250 of a portion of the pixel sensor array 102 is similar to the example implementation 200 of a portion of the pixel sensor array 102. However, in the example implementation 250, the layers of the electrochromic layer stack 234 are horizontally arranged as opposed to vertically arranged. Thus, the bottom transparent electrode 236 is laterally adjacent to the ion-storage layer 238, the electrolyte layer 240 is laterally adjacent the ion-storage layer 238, the electrochromic layer 242 is laterally adjacent to the electrolyte layer 240, and the top transparent electrode 244 is laterally adjacent to the electrochromic layer 242.

The z-direction thicknesses of each of the bottom transparent electrode 236, the ion-storage layer 238, the electrolyte layer 240, the electrochromic layer 242, and the top transparent electrode 244 may be expanded compared to the example implementation 200. Each of the bottom transparent electrode 236, the ion-storage layer 238, the electrolyte layer 240, the electrochromic layer 242, and the top transparent electrode 244 spans the full z-direction thickness of the electrochromic layer stack 234.

The lateral widths of each of the bottom transparent electrode 236, the ion-storage layer 238, the electrolyte layer 240, the electrochromic layer 242, and the top transparent electrode 244 may be reduced compared to the example implementation 200. Each of the bottom transparent electrode 236, the ion-storage layer 238, the electrolyte layer 240, the electrochromic layer 242, and the top transparent electrode 244 spans less than the full lateral width of the electrochromic layer stack 234. However, the electrochromic layer 242 may be sized to have a lateral width such that the electrochromic layer 242 is included over the photodiodes 204 of the white pixel sensor(s) 104 and the color pixel sensor(s) 106 of the pixel sensor array 102.

FIG. 2C illustrates another example implementation 252 of a portion of the pixel sensor array 102 of the image sensor device 100 that includes a white pixel sensor 104 and an adjacent color pixel sensor 106. As shown in FIG. 2C, the example implementation 252 of a portion of the pixel sensor array 102 is similar to the example implementation 200 of a portion of the pixel sensor array 102. However, in the example implementation 250, electrochromic layer stacks 234 are recessed in the isolation grid 224 above the photodiodes 204 of the color pixel sensors 106 of the pixel sensor array 102. Thus, electrochromic layer stacks 234 are omitted from above the photodiodes 204 of the white pixel sensors 104. This may enable a reduced z-direction height of the pixel sensor array 102 to be achieved.

Moreover, the color filters 230 of the color pixel sensors 106 are integrated into the electrochromic layer stacks 234. In particular, the color filters 230 of the color pixel sensors 106 are integrated into the electrochromic layers 242 of the electrochromic layer stacks 234. An electrochromic layer 242 may be formed of one or more materials having electrochromic properties and that can filter particular wavelengths of incident light, thereby enabling both color filtering and optical transmittance tuning to be achieved in the same layer. For example, a blue color filter 230 may be implemented as a Prussian blue (C₁₈Fe₇N₁₈) electrochromic layer 242 that can transition between transparent and semi-transparent blue. As another example, a green color filter 230 can be implemented as a Prussian green (C₃FeN₃) electrochromic layer 242 that can transition between transparent and semi-transparent green. Moreover, integrating a color filter 230 into an electrochromic layer 242 may enable the color filter 230 to be implemented with more robust materials than a standalone color filter 230, thereby increasing the operational lifetime of the color filter 230.

FIG. 2D illustrates another example implementation 254 of a portion of the pixel sensor array 102 of the image sensor device 100 that includes a white pixel sensor 104 and an adjacent color pixel sensor 106. As shown in FIG. 2D, the example implementation 254 of a portion of the pixel sensor array 102 is similar to the example implementation 252 of a portion of the pixel sensor array 102 in that electrochromic layer stacks 234 are recessed in the isolation grid 224 above the photodiodes 204 of the color pixel sensors 106 of the pixel sensor array 102. However, in the example implementation 254, the layers of the electrochromic layer stack 234 are horizontally arranged as opposed to vertically arranged. Thus, the bottom transparent electrode 236 is laterally adjacent to the ion-storage layer 238, the electrolyte layer 240 is laterally adjacent the ion-storage layer 238, the electrochromic layer 242 is laterally adjacent to the electrolyte layer 240, and the top transparent electrode 244 is laterally adjacent to the electrochromic layer 242.

The z-direction thicknesses of each of the bottom transparent electrode 236, the ion-storage layer 238, the electrolyte layer 240, the electrochromic layer 242, and the top transparent electrode 244 may be expanded compared to the example implementation 252. Each of the bottom transparent electrode 236, the ion-storage layer 238, the electrolyte layer 240, the electrochromic layer 242, and the top transparent electrode 244 spans the full z-direction thickness of the electrochromic layer stack 234.

The lateral widths of each of the bottom transparent electrode 236, the ion-storage layer 238, the electrolyte layer 240, the electrochromic layer 242, and the top transparent electrode 244 may be reduced compared to the example implementation 252. Each of the bottom transparent electrode 236, the ion-storage layer 238, the electrolyte layer 240, the electrochromic layer 242, and the top transparent electrode 244 spans less than the full lateral width of the electrochromic layer stack 234.

FIG. 2E illustrates another example implementation 256 of a portion of the pixel sensor array 102 of the image sensor device 100 that includes a white pixel sensor 104 and an adjacent color pixel sensor 106. As shown in FIG. 2E, the example implementation 256 of a portion of the pixel sensor array 102 is similar to the example implementation 200 of a portion of the pixel sensor array 102. However, in the example implementation 256, electrochromic layer stacks 234a are also recessed in the isolation grid 224 above the photodiodes 204 of the color pixel sensors 106 of the pixel sensor array 102, in addition to an electrochromic layer stack 234b being included above the isolation grid 224 of the pixel sensor array 102. The electrochromic layer stack 234b above the isolation grid 224, and the electrochromic layer stacks 234a recessed in the isolation grid 224, include layers that are stacked and vertically arranged in the z-direction in the image sensor device 100.

The combination of the electrochromic layer stack 234b above the isolation grid 224 and the electrochromic layer stacks 234a recessed in the isolation grid 224 enables the optical transmittance of the white pixel sensors 104 and the color pixel sensors 106 of the pixel sensor array 102 to be adjusted or modified (e.g., using the electrochromic layer stackb above the isolation grid 224), and enables the operational lifetime of the color filters 230 of the color pixel sensors 106 to be increased (e.g., using the electrochromic layer stacks 234a recessed in the isolation grid 224). The electrochromic layer stack 234b above the isolation grid 224 may be independently controllable relative to the electrochromic layer stacks 234a recessed in the isolation grid 224. Moreover, the electrochromic layer stacks 234a recessed in the isolation grid 224 may each be independently controllable or may be collectively controlled.

FIG. 2F illustrates another example implementation 258 of a portion of the pixel sensor array 102 of the image sensor device 100 that includes a white pixel sensor 104 and an adjacent color pixel sensor 106. As shown in FIG. 2F, the example implementation 258 of a portion of the pixel sensor array 102 is similar to the example implementation 252 of a portion of the pixel sensor array 102 in that electrochromic layer stacks 234a are also recessed in the isolation grid 224 above the photodiodes 204 of the color pixel sensors 106 of the pixel sensor array 102, in addition to an electrochromic layer stack 234b being included above the isolation grid 224 of the pixel sensor array 102. However, in the example implementation 258, the layers of the electrochromic layer stacks 234a embedded in the isolation grid 224 for the color pixel sensors 106 are horizontally arranged as opposed to being vertically arranged as in the example implementation 256. Thus, the bottom transparent electrode 236 is laterally adjacent to the ion-storage layer 238, the electrolyte layer 240 is laterally adjacent the ion-storage layer 238, the electrochromic layer 242 is laterally adjacent to the electrolyte layer 240, and the top transparent electrode 244 is laterally adjacent to the electrochromic layer 242 in the electrochromic layer stacks 234a embedded in the isolation grid 224 for the color pixel sensors 106.

FIG. 2G illustrates another example implementation 260 of a portion of the pixel sensor array 102 of the image sensor device 100 that includes a white pixel sensor 104 and an adjacent color pixel sensor 106. As shown in FIG. 2G, the example implementation 260 of a portion of the pixel sensor array 102 is similar to the example implementation 252 of a portion of the pixel sensor array 102 in that electrochromic layer stacks 234a are also recessed in the isolation grid 224 above the photodiodes 204 of the color pixel sensors 106 of the pixel sensor array 102, in addition to an electrochromic layer stack 234b being included above the isolation grid 224 of the pixel sensor array 102. However, in the example implementation 260, the layers of the electrochromic layer stack 234b above the isolation grid 224 are horizontally arranged as opposed to being vertically arranged as in the example implementation 256. Thus, the bottom transparent electrode 236 is laterally adjacent to the ion-storage layer 238, the electrolyte layer 240 is laterally adjacent the ion-storage layer 238, the electrochromic layer 242 is laterally adjacent to the electrolyte layer 240, and the top transparent electrode 244 is laterally adjacent to the electrochromic layer 242 in the electrochromic layer stack 234b above the isolation grid 224.

FIG. 2H illustrates another example implementation 262 of a portion of the pixel sensor array 102 of the image sensor device 100 that includes a white pixel sensor 104 and an adjacent color pixel sensor 106. As shown in FIG. 2H, the example implementation 262 of a portion of the pixel sensor array 102 is similar to the example implementation 252 of a portion of the pixel sensor array 102 in that electrochromic layer stacks 234a are also recessed in the isolation grid 224 above the photodiodes 204 of the color pixel sensors 106 of the pixel sensor array 102, in addition to an electrochromic layer stackb 234 being included above the isolation grid 224 of the pixel sensor array 102. However, in the example implementation 262, the layers of the electrochromic layer stack 234b above the isolation grid 224 are horizontally arranged as opposed to being vertically arranged as in the example implementation 256. Moreover, the layers of the electrochromic layer stacks 234a embedded in the isolation grid 224 for the color pixel sensors 106 are also horizontally arranged as opposed to being vertically arranged as in the example implementation 256.

As indicated above, FIGS. 2A-2H are provided as examples. Other examples may differ from what is described with regard to FIGS. 2A-2H.

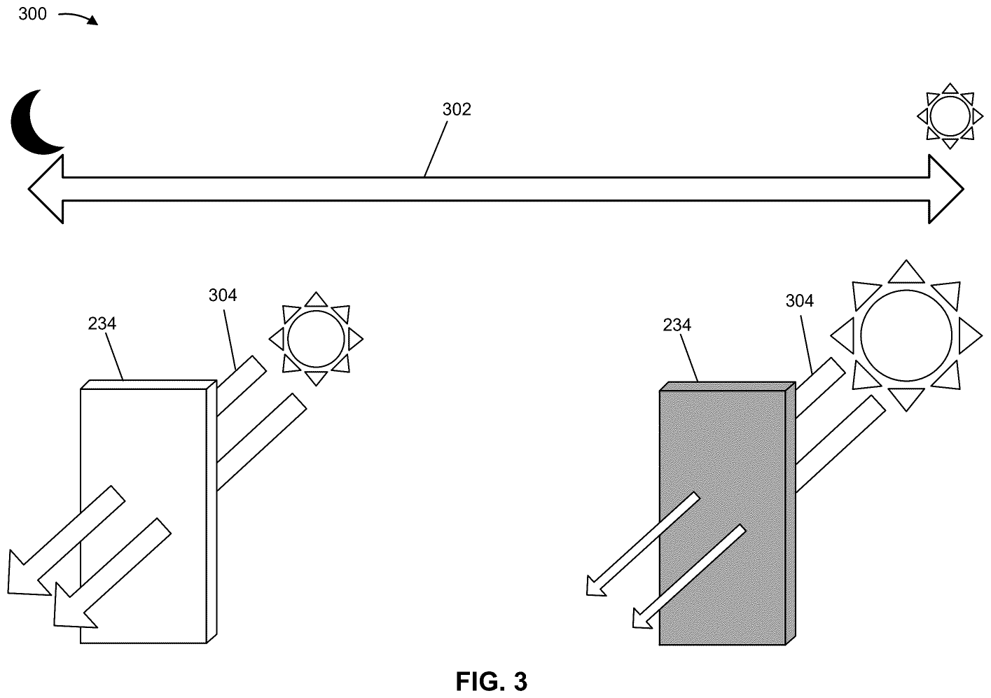

FIG. 3 is a diagram of an example implementation 300 of tuning optical transmittance of an electrochromic layer stack 234 based on the level of illuminance 302 in the surrounding environment. As shown in FIG. 3, the level of illuminance 302 in the surrounding environment can range for dark (e.g., as low as a few hundred lux or less in underground roadways such as tunnels) to bright (e.g., up to 1 million lux or greater for outdoor environments).

The optical transmittance of an electrochromic layer stack 234 included in a pixel sensor array 102 described herein can be tuned for the level of illuminance 302 in the surrounding environment to tune the optical intensity of incident light 304 received at the photodiodes 204 of the pixel sensors (e.g., the white pixels sensors 104, the color pixel sensors 106) of the pixel sensor array 102.

For example, the optical transmittance of an electrochromic layer stack 234 included in a pixel sensor array 102 described herein can be tuned to have a high optical transmittance if the level of illuminance 302 in the surrounding environment is low, such as in cases of driving at night, driving in a parking garage, or driving in a tunnel. This enables a greater amount of the incident light 304 to pass through the electrochromic layer stack 234 to the photodiodes 204 of the pixel sensors of the pixel sensor array 102 such that sufficient optical intensity of the incident light 304 is received at the photodiodes 204.

As another example, the optical transmittance of an electrochromic layer stack 234 included in a pixel sensor array 102 described herein can be tuned to have a low optical transmittance if the level of illuminance 302 in the surrounding environment is high, such as in cases of driving in a daytime outdoor environment. This enables a lesser amount of the incident light 304 to pass through the electrochromic layer stack 234 to the photodiodes 204 of the pixel sensors of the pixel sensor array 102 such that the optical intensity of the incident light 304 received at the photodiodes 204 does not overly saturate the photodiodes 204 and cause loss of image detail.

The electrochromic layer stack 234 can be used to dynamically adjust for rapidly changing lighting conditions. For example, electrochromic layer stack 234 can quickly adjust optical transmittance to account for exposure to reflective surfaces and/or to account for intermittent exposure to a light source (where trees, buildings, or other objects may intermittently block sun exposure), among other examples.

In some implementations, an electrochromic layer stack 234 included in a pixel sensor array 102 may be independently tuned to adjust the optical transmittance of visible light and infrared light. Thus, the electrochromic layer stack 234 can be configured in a high optical transmittance state for both visible light and infrared light, in a high optical transmittance state for visible light and in a low optical transmittance state for infrared light, in a low optical transmittance state for visible light and in a high optical transmittance state for infrared light, or in a low optical transmittance state for both visible light and infrared light.

As indicated above, FIG. 3 is provided as an example. Other examples may differ from what is described with regard to FIG. 3.

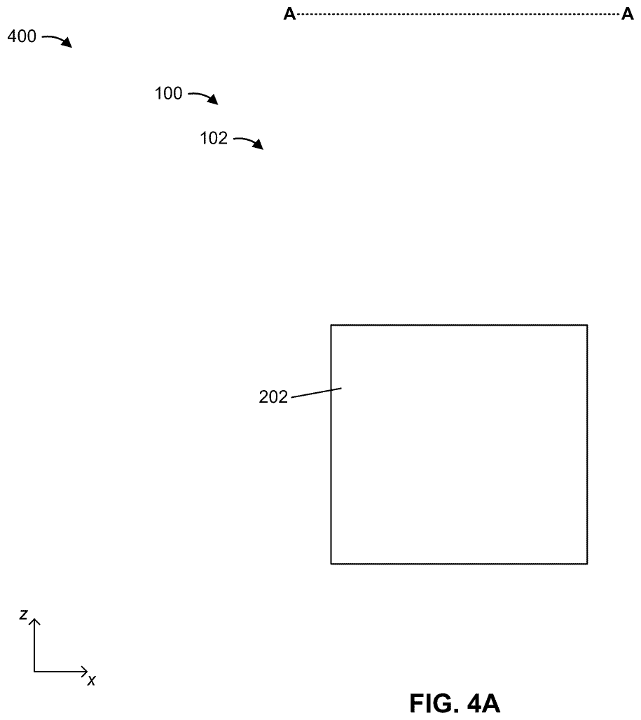

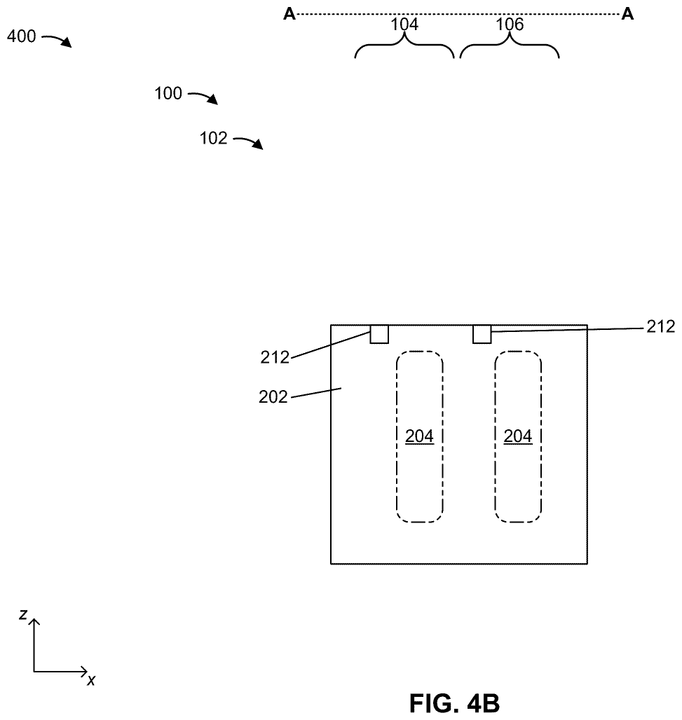

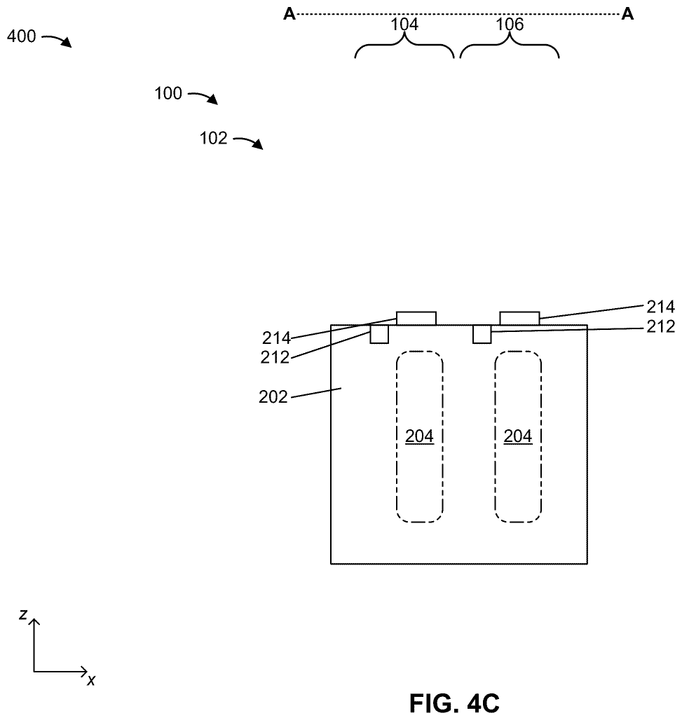

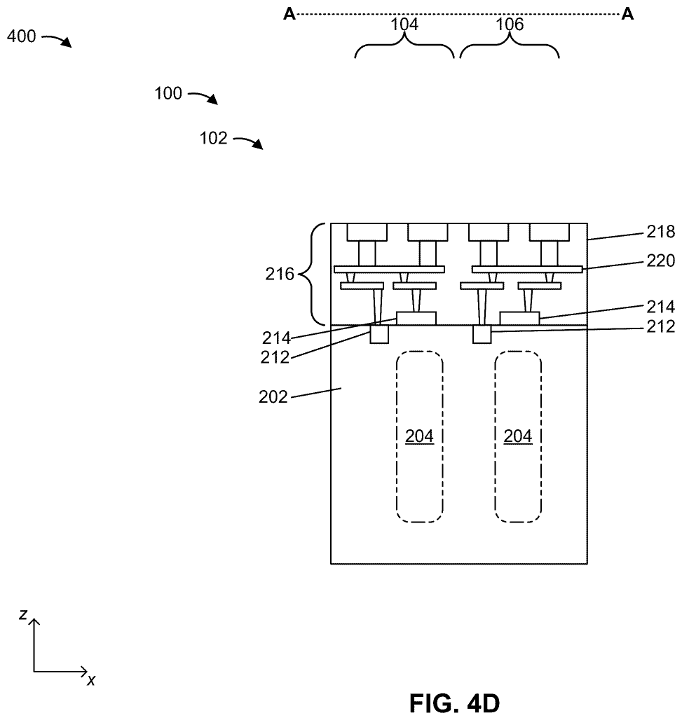

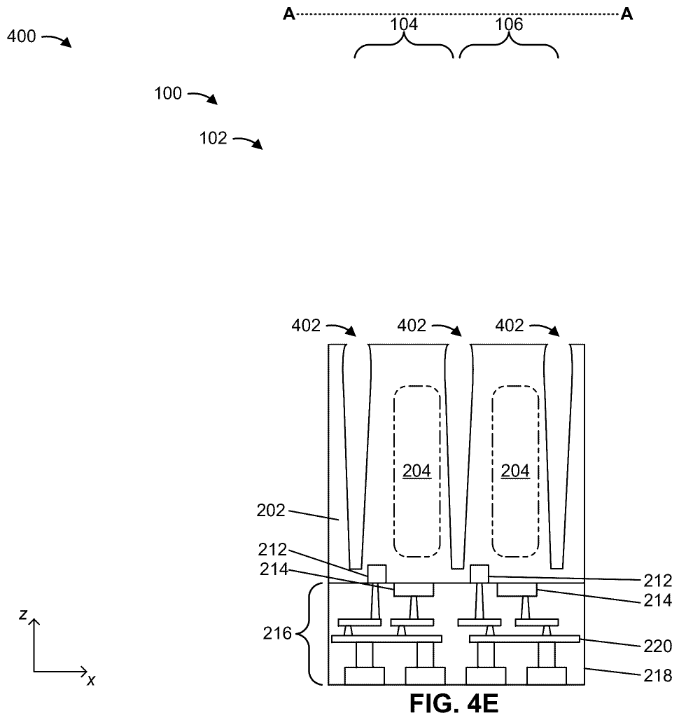

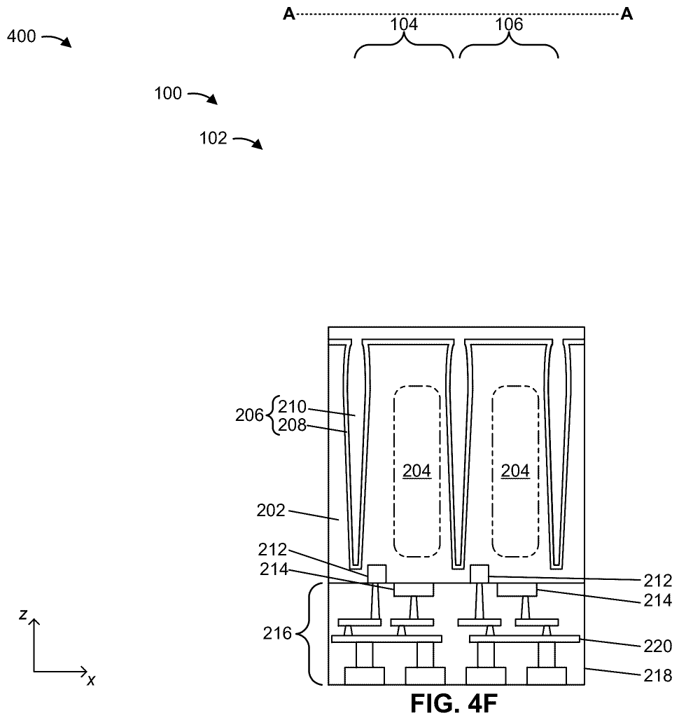

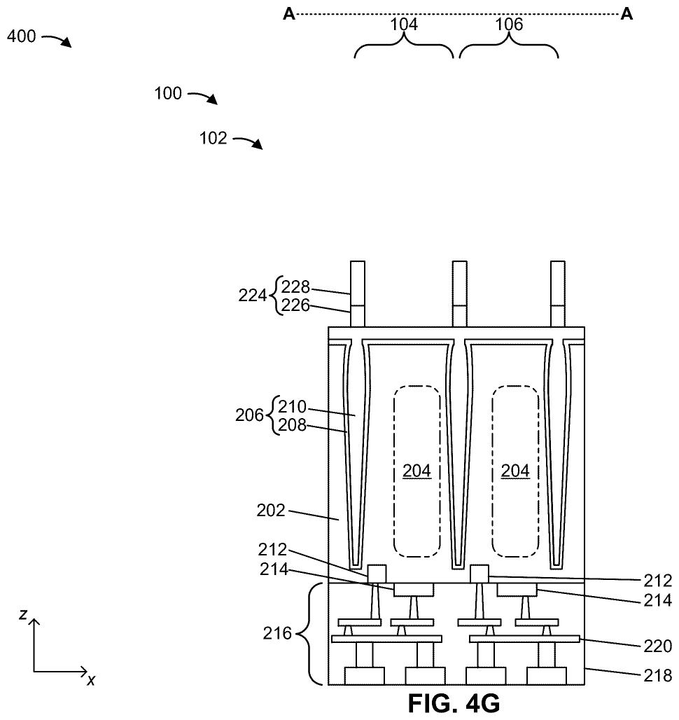

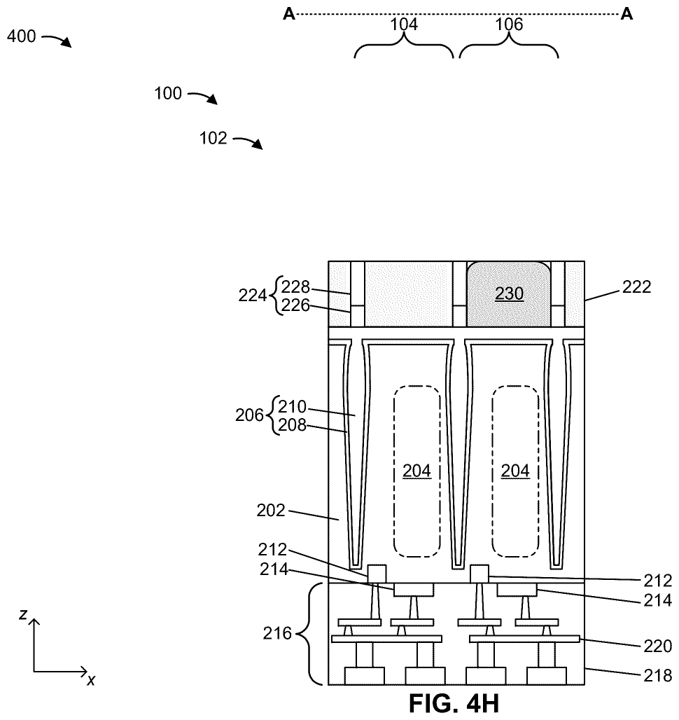

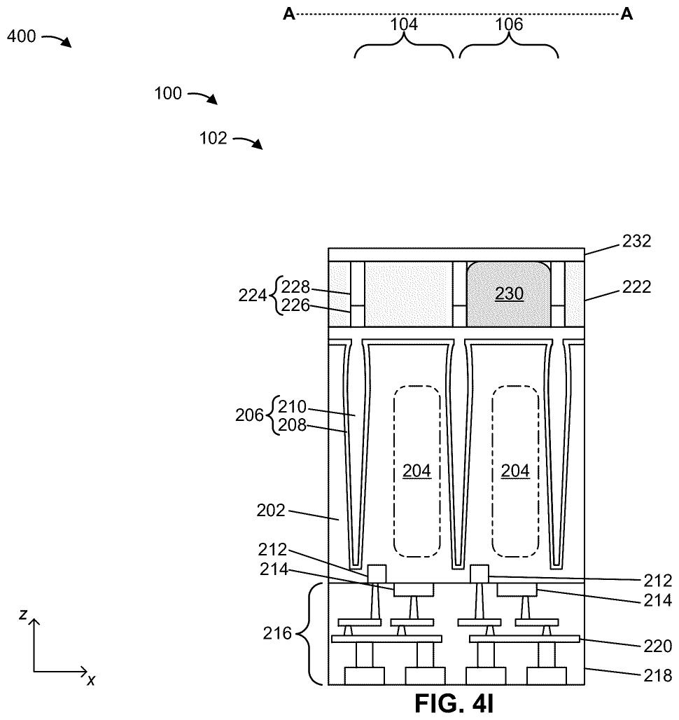

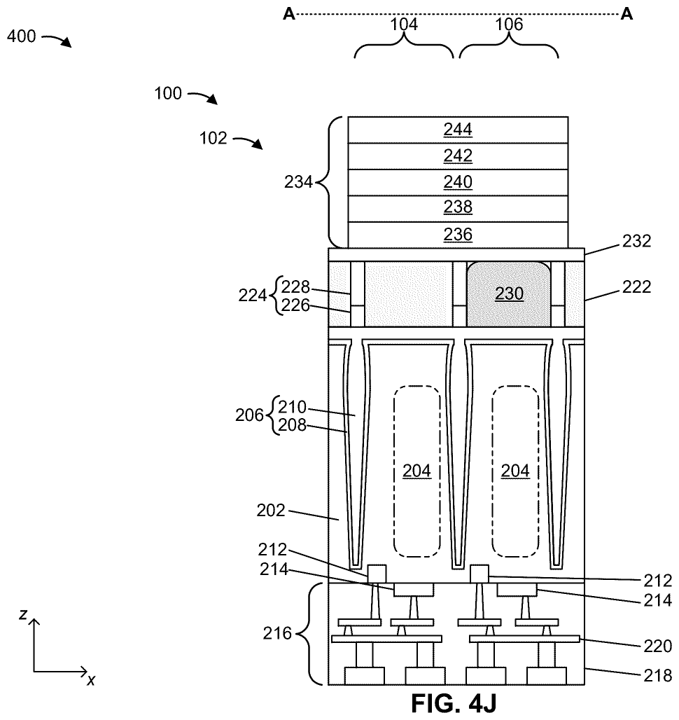

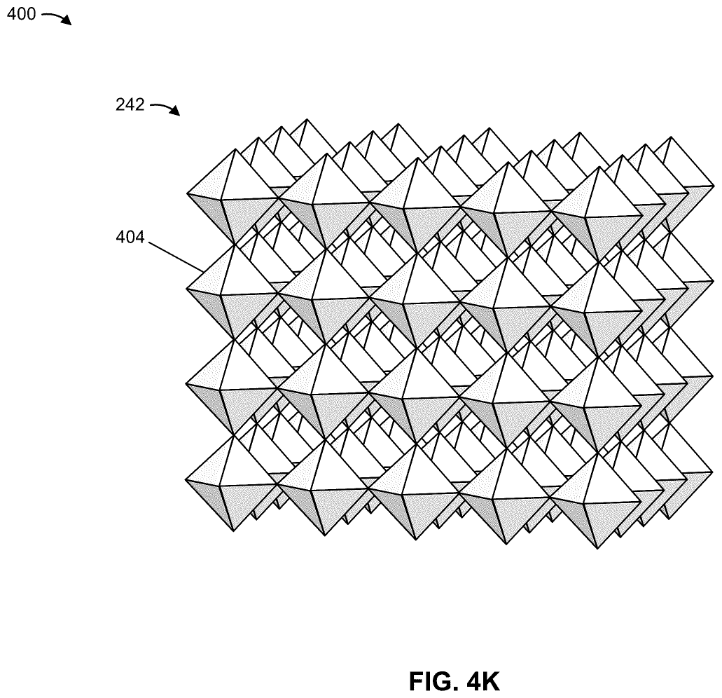

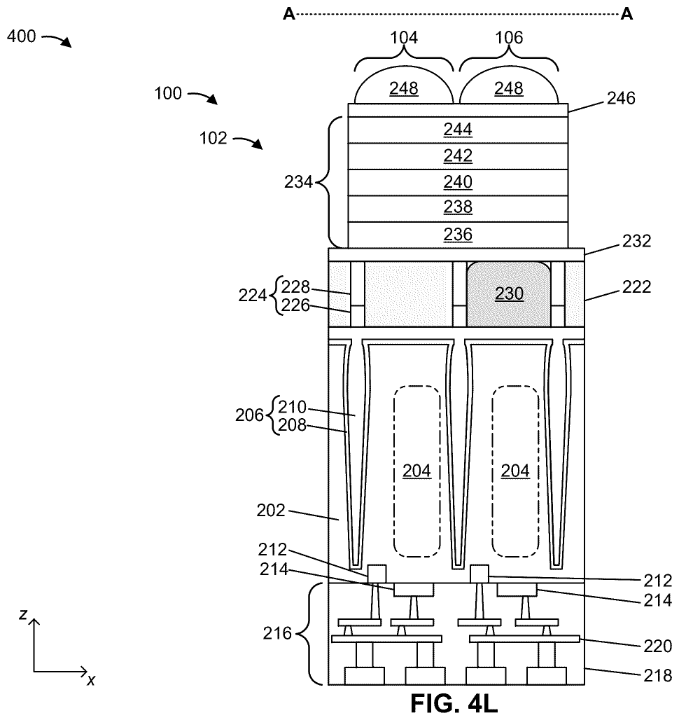

FIGS. 4A-4L are diagrams of an example implementation 400 of forming an image sensor device described herein. While the example implementation 400 includes forming the pixel sensor array 102 in the image sensor device 100 described herein, the semiconductor processing techniques may be used to form another pixel sensor array described herein, such as one or more of a pixel sensor array 102a, a pixel sensor array 102b, and/or a pixel sensor array 102c of an image sensor device illustrated and described in connection with FIGS. 5A-5C and/or 6A-6H, among other examples. In some implementations, one or more of the semiconductor processing operations described in connection with FIGS. 4A-4L may be performed using one or more semiconductor processing tools, such as a deposition tool, an exposure tool, a developer tool, an etch tool, a planarization tool, a plating tool, an ion implantation tool, and/or a bonding tool, among other examples.

Turning to FIG. 4A, one or more of the semiconductor processing operations in the example implementation 400 may be performed in connection with the substrate 202. The substrate 202 may be provided as a semiconductor wafer or another type of semiconductor work piece.

As shown in FIG. 4B, a plurality of regions of the substrate 202 may be doped to form photodiodes 204 for one or more white pixel sensors 104 and/or may be doped to form photodiodes 204 of one or more color pixel sensors 106. An ion implantation tool may be used to dope the substrate 202 to form one or more n-type regions and/or one or more p-type regions of the photodiodes 204. The ion implantation tool may be used to implant p′ ions in the substrate 202 to form the p-type region(s) and/or may implant n′ ions in the substrate 202 to form the n-type region(s).

As further shown in FIG. 4B, one or more regions of the substrate 202 may be doped to form the FD nodes 212 of the white pixel sensors 104 and/or may be doped to form the FD nodes 212 of the color pixel sensors 106. In some implementations, an ion implantation tool may be used to dope by implanting n′ ions in the substrate 202 to form the FD nodes 212.

As shown in FIG. 4C, transfer gates 214 of the white pixel sensors 104 and transfer gates 214 of the color pixel sensors 106 may be formed over the front side surface of the substrate 202. In some implementations, a gate dielectric layer may be formed on the front side surface of the substrate 202, and the transfer gates 214 may be formed over and/or on the gate dielectric layer. In some implementations, a deposition tool is used to deposit the transfer gates 214. In some implementations, the transfer gates 214 may include polysilicon that is doped with one or more types of dopants. In some implementations, the transfer gates 214 may include high-k dielectric and metal materials (e.g., metal gates or MGs).

As shown in FIG. 4D, an interconnect layer 216 may be formed above the front side surface of the substrate 202. Forming the interconnect layer 216 may include forming one or more dielectric layers 218 and forming one or more metallization layers 220 in the one or more dielectric layers 218. For example, a first dielectric layer 218 may be formed and patterned to form recesses in the first dielectric layer 218, and a first metallization layer 220 may be formed in the recesses in the first dielectric layer 218. Subsequent layers of the interconnect layer 216 may be formed in a similar manner.

A deposition tool may be used to deposit the dielectric layer(s) 218 using a physical vapor deposition (PVD) technique, an atomic layer deposition (ALD) technique, a chemical vapor deposition (CVD) technique, an oxidation technique, and/or another type of deposition technique. In some implementations, a planarization tool may be used to planarize the dielectric layer(s) 218 after the dielectric layer(s) 218 are deposited.

In some implementations, a pattern in a photoresist layer is used to etch a dielectric layer 218 to form the recesses in the dielectric layer 218 for the metallization layers 220. In these implementations, a deposition tool may be used to form the photoresist layer on a dielectric layer 218. An exposure tool may be used to expose the photoresist layer to a radiation source to pattern the photoresist layer. A developer tool may be used to develop and remove portions of the photoresist layer to expose the pattern. An etch tool may be used to etch the dielectric layer 218 based on the pattern to form the recesses. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 218 based on a pattern.

A deposition tool may be used to deposit the metallization layers 220 using a PVD technique, an ALD technique, a CVD technique, an electroplating (e.g., an electro-chemical plating) technique, and/or another type of deposition technique. In some implementations, a planarization tool may be used to planarize the metallization layers 220 after the metallization layers 220 are deposited. In some implementations, a seed layer is first deposited, and a metallization layer 220 is formed on the seed layer. In some implementations, one or more liners (e.g., a barrier layer, an adhesion layer) is first deposited, and a metallization layer 220 is formed on the one or more liners.

As shown in FIG. 4E, backside processing may be performed on the backside surface of the substrate 202. Recesses 402 may be formed into the substrate 202 from the backside surface of the substrate 202. In some implementations, a pattern in a photoresist layer is used to pattern the recesses 402. The recesses 402 may include a plurality of interconnected trenches that extend into the substrate 202 to form a grid around the photodiodes 204 and, in some implementations, around the FD nodes 212.

A deposition tool may be used to form the photoresist layer on the backside surface of the substrate 202. An exposure tool may be used to expose the photoresist layer to a radiation source to pattern the photoresist layer. A developer tool may be used to develop and remove portions of the photoresist layer to expose the pattern. An etch tool may be used to etch the substrate 202 based on the pattern to form the recesses 402. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming the recesses 402.

In some implementations, a cyclic etch technique is used to form the recesses 402 to have a relatively high aspect ratio between the depth of the recesses 402 and the lateral width of the recesses 402. For example, a cyclic etch technique is used to form the recesses 402 such that the recesses 402 have an aspect ratio between the depth of the recesses 402 and the lateral width of the recesses 402 that is at least approximately 8:1 or greater. However, other values for the aspect ratio of the recesses 402 are within the scope of the present disclosure. The cyclic etch technique may include a plurality of deposition and etch cycles that are performed using protective liners to minimize lateral etching. For example, a deposition and etch cycle may include etching a recess 402 to a first depth in the substrate 202, forming a protective liner on the sidewalls and bottom surface of the recess 402, etching the protective liner to remove the protective liner from the bottom surface of the recess 402, and etching the bottom of the recess 402 to increase the depth of the recess 402 to a second depth while the protective liner protects the sidewalls of the recess 402 from lateral etching. Additional cycles may be performed to achieve a particular depth for the recesses 402.

As shown in FIG. 4F, the recesses 402 are filled with one or more liners 208 and a fill layer 210 to form the isolation structure 206 in the recesses 402. The isolation structure 206 may extend into the substrate 202 and laterally around the photodiodes 204. As further shown in FIG. 4F, in some implementations, the material of the liner(s) 208 and/or the material of the fill layer 210 may be deposited over the backside surface of the substrate 202.

A deposition tool may be used to deposit the one or more liners 208 in the recesses 402 using a conformal deposition technique such as ALD or CVD, among other examples. The one or more liners 208 may be conformally deposited on the sidewalls and the bottom surface of the recesses 402 such that the one or more liners 208 conform to the profile of the recesses 402. A deposition tool may be used to deposit the filler layer 210 using a PVD technique, an ALD technique, a CVD technique, an oxidation technique, and/or another type of deposition technique.

In some implementations, a planarization tool may be used to perform a planarization operation (e.g., a chemical mechanical planarization (CMP) operation) to planarize the backside of the substrate 202 to remove the one or more liners 208 and/or the fill layer 210 from the backside surface of the substrate 202. In some implementations, the planarization operation is omitted (or stops before the one or more liners 208 and/or the fill layer 210 are removed from the backside surface of the substrate 202) such that the one or more liners 208 and/or the fill layer 210 remain on the backside surface of the substrate 202.

As shown in FIG. 4G, the isolation grid 224 may be formed above the backside surface of the substrate 202. The isolation grid 224 may be formed over the isolation structure 206 such that the isolation grid 224 conforms to the grid top view shape of the isolation structure 206. A deposition tool may deposit the layer(s) of the isolation grid 224 using a PVD technique, an ALD technique, a CVD technique, an oxidation technique, a plating technique (e.g., an electroplating technique, an electro-chemical plating technique), and/or another suitable deposition technique. In some implementations, a metal layer 226 is deposited, and a dielectric layer 228 is deposited on the metal layer 226. A pattered masking layer may be formed above the dielectric layer 228 and used to etch the metal layer 226 and the dielectric layer 228 to form the isolation grid 224.

As shown in FIG. 4H, the color filters 230 may be formed in between the isolation grid 224 above the photodiodes 204 of the color pixel sensors 106. Moreover, the buffer layer 222 may be formed in the remaining areas in between the isolation grid 224. In some implementations, the color filters 230 are formed prior to formation of the buffer layer 222. In some implementations, the buffer layer 222 is formed prior to formation of the color filters 230, and the buffer layer 222 is etched to remove portions of the buffer layer 222 above the photodiodes 204 of the color pixel sensors 106. The color filters 230 may then be formed above the photodiodes 204 of the color pixel sensors 106.

A deposition tool may deposit the buffer layer 222 and the color filters 230 each using a PVD technique, an ALD technique, a CVD technique, an oxidation technique, and/or another suitable deposition technique. In some implementations, the buffer layer 222 and/or the color filters 230 are formed over the isolation grid 224. In these implementations, a planarization tool may be used to perform a planarization operation (e.g., a CMP operation) to planarize the buffer layer 222 and/or the color filters 230. The top surface of the buffer layer 222, the top surfaces of the color filters 230, and/or the top surfaces of the isolation grid 224 may be approximately co-planar after the planarization operation.

As shown in FIG. 4I, the buffer layer 232 may be formed over and/or on the buffer layer 222. A deposition tool may deposit the buffer layer 232 using a PVD technique, an ALD technique, a CVD technique, an oxidation technique, and/or another suitable deposition technique. In these implementations, a planarization tool may be used to perform a planarization operation (e.g., a CMP operation) to planarize the buffer layer 232.

As shown in FIG. 4J, an electrochromic layer stack 234 is provided above the buffer layer 232. The electrochromic layer stack 234 is provided such that the electrochromic layer stack 234 is located above the photodiodes 204 of the white pixel sensors 104 and/or above the photodiodes 204 of the color pixel sensors 106. Alternatively, a plurality of electrochromic layer stacks 234 are provided in between the isolation grid 224 above the photodiodes 204 of the color pixel sensors 106, and the color filters 230 of the color pixel sensors 106 are integrated into the electrochromic layer 242 of the electrochromic layer stack 234. Alternatively, a plurality of electrochromic layer stacks 234 are provided in between the isolation grid 224 above the photodiodes 204 of the color pixel sensors 106, in addition to the electrochromic layer stack 234 being provided above the buffer layer 232.

In some implementations, the electrochromic layer stack 234 is formed prior to being placed on the buffer layer 232 (or in between the isolation grid 224). In these implementations, the electrochromic layer stack 234 is formed in a separate process, and then placed on the pixel sensor array 102 after manufacturing. An electrochromic layer stack 234 may be provided as a vertical stack (e.g., z-direction stack), such as in the example implementations 200, 252, 256, 258, and/or 260. Additionally and/or alternatively, electrochromic layer stack 234 may be provided as a horizonal arrangement of layers, such as in the example implementations 250, 254, 258, 260, and/or 262.

In some implementations, electrochromic layer stack 234 is formed on the buffer layer 232 (or formed in between the isolation grid 224). For example, the bottom transparent electrode 236 may be dispensed, deposited, or placed (e.g., on the buffer layer 232, on the backside surface of the substrate 202). The ion-storage layer 238 may be dispensed, deposited, or placed onto the bottom transparent electrode 236. The electrolyte layer 240 may be dispensed, deposited, or placed onto the ion-storage layer 238. The electrochromic layer 242 may be dispensed, deposited, or placed onto the electrolyte layer 240. The top transparent electrode 244 may be dispensed, deposited, or placed onto the electrochromic layer 242.

As shown in FIG. 4K, the electrochromic layer 242 may be formed to have a particular crystal structure 404. In some implementations, the electrochromic layer 242 is formed to have a particular crystal structure 404 to reduce or prolong the decay of the electrochromic layer 242, which may increase the operational lifetime of the electrochromic layer 242. For example, the electrochromic layer 242 may be formed of a material in which the bonds between atoms of the material have a high degree of freedom and a high bonding strength. As an example, the electrochromic layer 242 may be formed of WO₆ tungsten oxide such that the crystal structure 404 is an octahedral structure in which oxygen and tungsten are bonded together by covalent bonds (e.g., double bonds such as W═O═W). The bonds of the WO₆ tungsten oxide provide strong resistance to bond breakage, resulting in increased longevity and decreased rate of decay over time. However, other higher order crystal structures 404 for the electrochromic layer 242 are within the scope of the present disclosure.

As shown in FIG. 4L, another buffer layer 246 is formed above the electrochromic layer stack 234, and the micro-lenses 248 may be formed or provided on the buffer layer 246. A deposition tool may deposit the buffer layer 246 using a PVD technique, an ALD technique, a CVD technique, an oxidation technique, and/or another suitable deposition technique. In these implementations, a planarization tool may be used to perform a planarization operation (e.g., a CMP operation) to planarize the buffer layer 246.

As indicated above, FIGS. 4A-4L are provided as an example. Other examples may differ from what is described with regard to FIGS. 4A-4L.

FIGS. 5A-5C are diagrams of example image sensor devices described herein. Each of the example image sensor devices illustrated and described in connection with FIGS. 5A-5C include a plurality of pixel sensor arrays, including at least one monochromatic pixel sensor array. For example, the each of the example image sensor devices illustrated and described in connection with FIGS. 5A-5C include at least one pixel sensor array 102 as illustrated and described in connection with one or more of FIGS. 1 and/or 2A-2H. The monochromatic pixel sensor array may be accompanied by other monochromatic pixel sensor arrays to facilitate monochromatic sensing and/or machine reading for multiple monochromatic colors, and/or may be accompanied by an RGB pixel sensor array (or another type of full-color pixel sensor array). The monochromatic pixel sensor array(s) included in the example image sensor devices illustrated and described in connection with FIGS. 5A-5C may be used for monochromatic pixel sensor array configured for monochromatic sensing and/or machine reading (e.g., reading of road signs, readings of markings on vehicles). In implementations in which a full-color pixel sensor array is included, the full-color pixel sensor may be used for comparison, verification, and/or enhancement of the monochromatic sensing and/or machine reading outputs from the monochromatic pixel sensor array(s).

FIG. 5A illustrates an example image sensor device 500 in which a monochromatic pixel sensor array 102a and a full-color pixel sensor array 102b are included. The monochromatic pixel sensor array 102a and the full-color pixel sensor array 102b are independently controllable and are connected to independent control circuitry. This enables the monochromatic pixel sensor array 102a and the full-color pixel sensor array 102b to generate independent outputs based on incident light.

The monochromatic pixel sensor array 102a is similar to the pixel sensor array 102 as illustrated and described in connection with FIG. 1 and may include a plurality of white pixel sensors 104 and a plurality of color pixel sensors 106 (e.g., single-color pixel sensors or monochromatic pixel sensors). The monochromatic pixel sensor array 102a also includes one or more electrochromic layer stacks 234 that may be arranged according to one or more of the example implementations illustrated and described in connection with FIGS. 2A-2H.

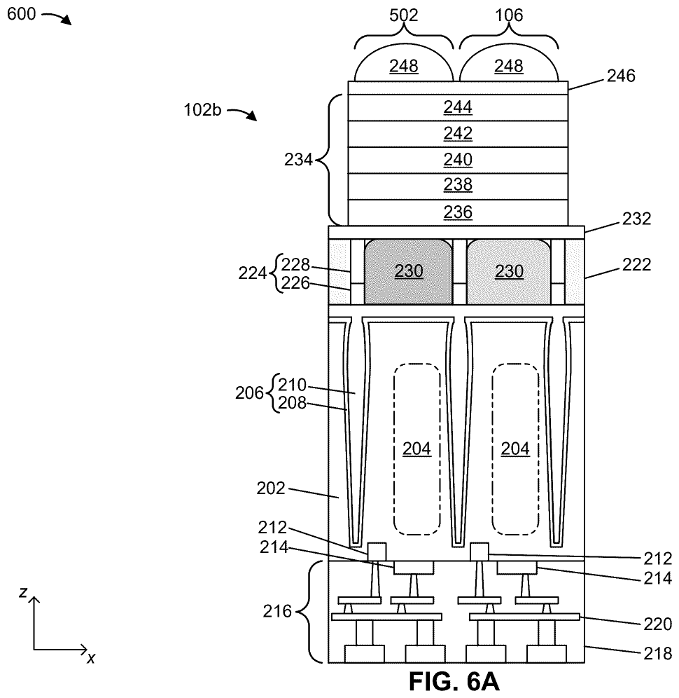

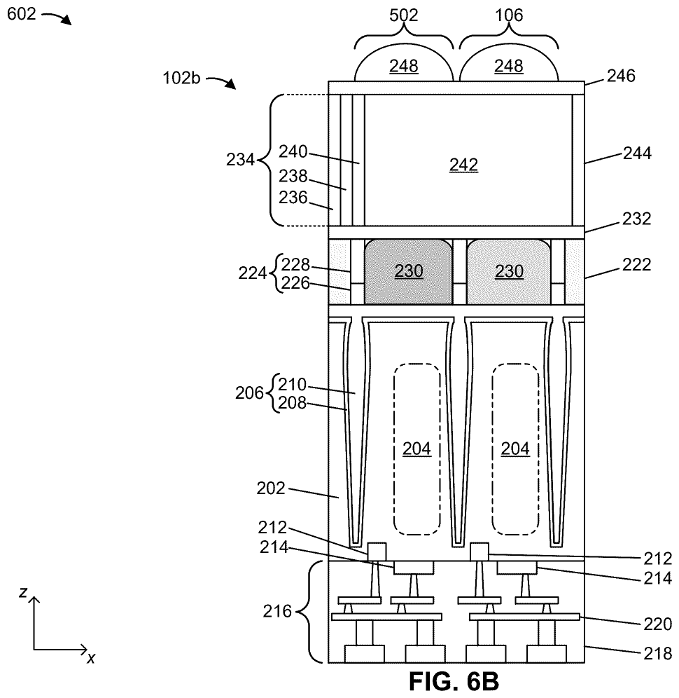

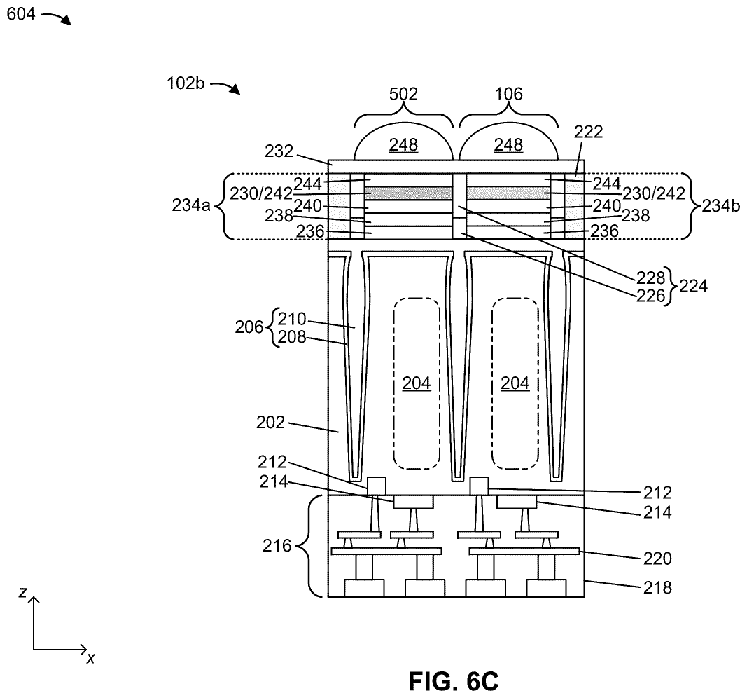

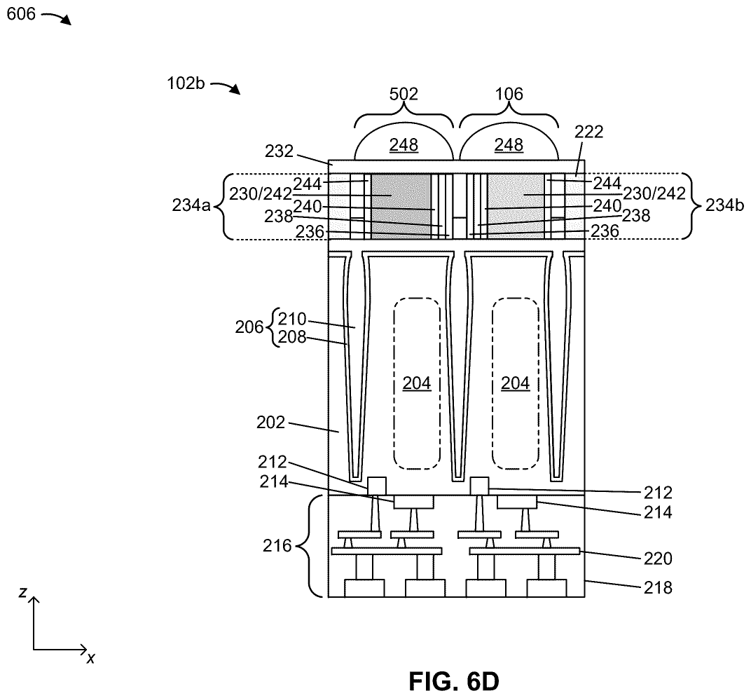

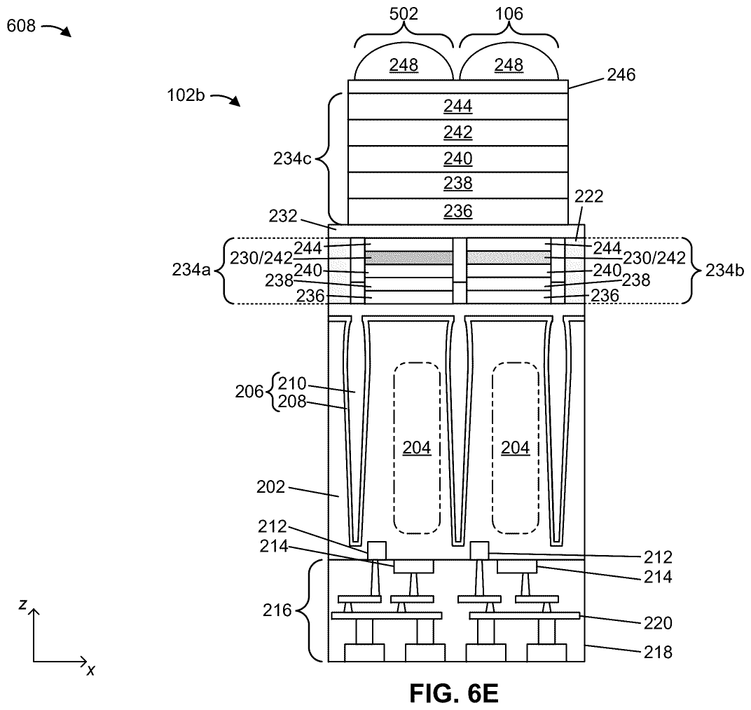

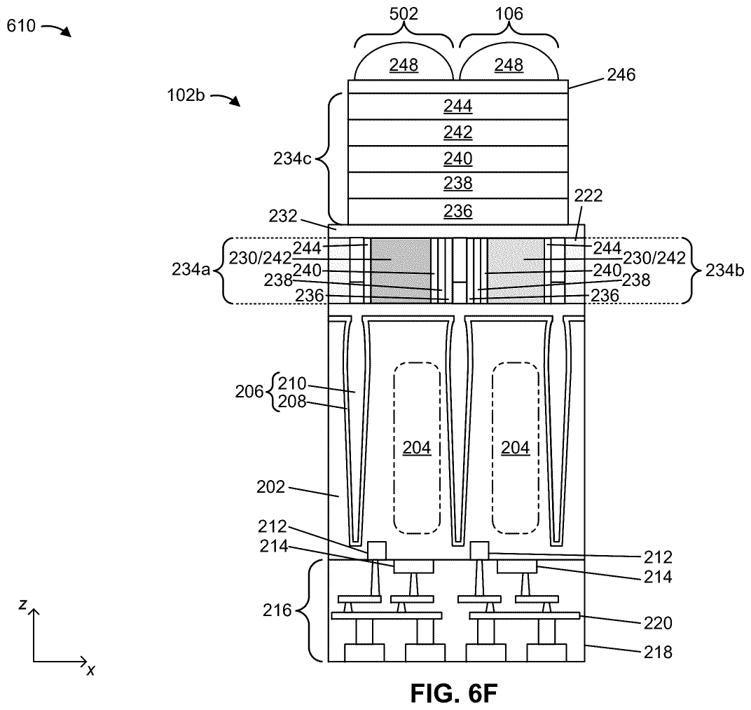

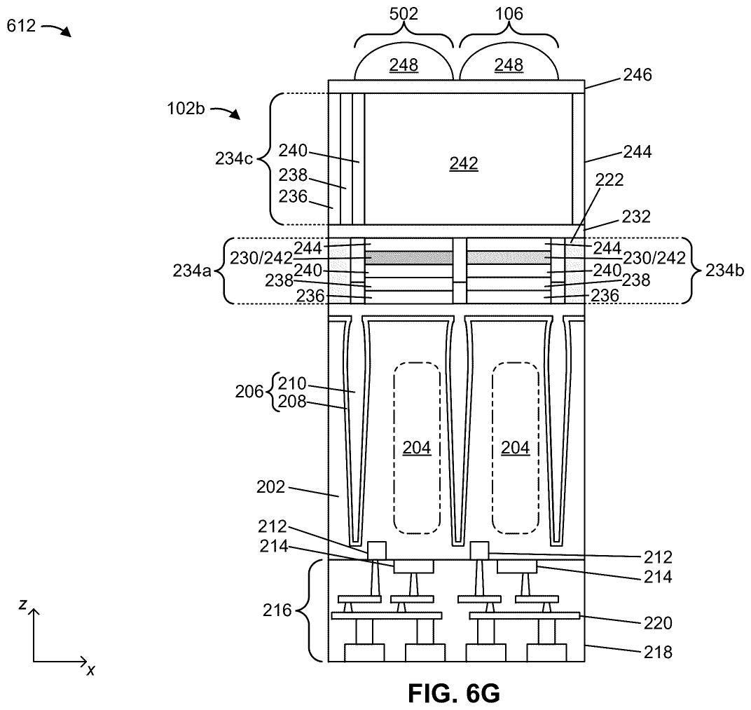

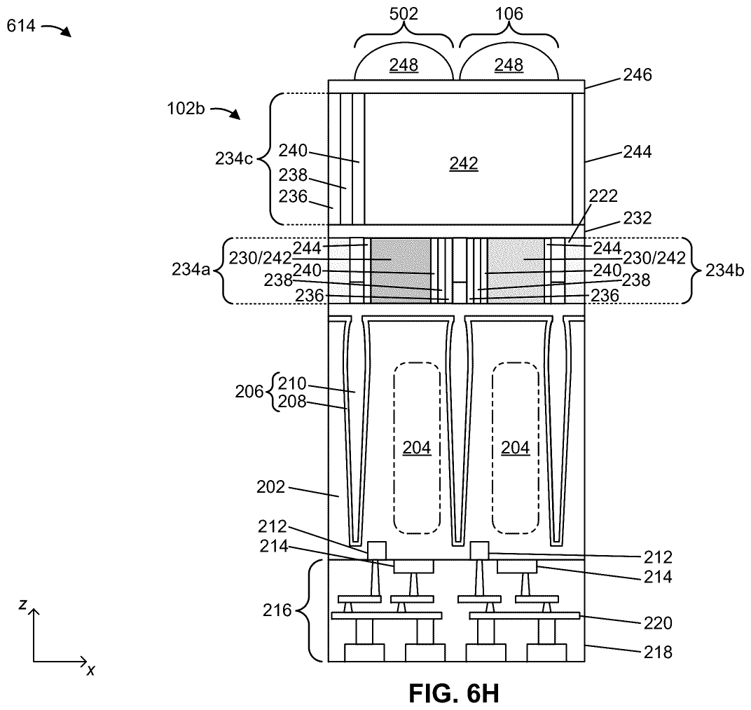

The full-color pixel sensor array 102b includes a plurality of color pixel sensors, including color pixel sensors 106, color pixel sensors 502, and color pixel sensors 504. The color pixel sensors 106 502, and 504 may be arranged in a grid in an x-y plane in the pixel sensor array 102b. The full-color pixel sensor array 102b also includes one or more electrochromic layer stacks 234 that may be arranged according to one or more of the example implementations illustrated and described in connection with FIGS. 6A-6H.

In some implementations, the color pixel sensors 106 are red pixel sensors (e.g., in both the monochromatic pixel sensor array 102a and in the full-color pixel sensor array 102b), the color pixel sensors 502 are green pixel sensors, and the color pixel sensors 504 are blue pixel sensors. In some implementations, the color pixel sensors 106 are green pixel sensors (e.g., in both the monochromatic pixel sensor array 102a and in the full-color pixel sensor array 102b), the color pixel sensors 502 are blue pixel sensors, and the color pixel sensors 504 are red pixel sensors. In some implementations, the color pixel sensors 106 are blue pixel sensors (e.g., in both the monochromatic pixel sensor array 102a and in the full-color pixel sensor array 102b), the color pixel sensors 502 are red pixel sensors, and the color pixel sensors 504 are green pixel sensors.

In some implementations, the color pixel sensors 106, color pixel sensors 502, and color pixel sensors 504 may include another combination of colors, such as cyan, magenta, and yellow (CMYK) pixel sensors.

FIG. 5B illustrates an example image sensor device 506 that includes a plurality of monochromatic pixel sensor arrays, including a monochromatic pixel sensor array 102a and a monochromatic pixel sensor array 102c. The monochromatic pixel sensor array 102a and the monochromatic pixel sensor array 102c are independently controllable and are connected to independent control circuitry. This enables the monochromatic pixel sensor array 102a and the monochromatic pixel sensor array 102c to generate independent outputs based on incident light.

The monochromatic pixel sensor array 102a and the monochromatic pixel sensor array 102c are each similar to the pixel sensor array 102 as illustrated and described in connection with FIG. 1 and may include a plurality of white pixel sensors 104 and a plurality of color pixel sensors 106 (e.g., single-color pixel sensors or monochromatic pixel sensors). However, the monochromatic pixel sensor array 102a and the monochromatic pixel sensor array 102c include different types of color pixel sensors. For example, the monochromatic pixel sensor array 102a may include color pixel sensors 106 and the monochromatic pixel sensor array 102c may include color pixel sensors 502. In some implementations, the color pixel sensors 106 may include red pixel sensors and the color pixel sensors 502 may include blue pixel sensors. In some implementations, the color pixel sensors 106 may include blue pixel sensors and the color pixel sensors 502 may include green pixel sensors. In some implementations, the color pixel sensors 106 may include green pixel sensors and the color pixel sensors 502 may include red pixel sensors. Other combinations of color pixel sensors are within the scope of the present disclosure.

The monochromatic pixel sensor array 102a and the monochromatic pixel sensor array 102c each include one or more electrochromic layer stacks 234 that may be arranged according to one or more of the example implementations illustrated and described in connection with FIGS. 2A-2H.

FIG. 5C illustrates an example image sensor device 508 that includes a plurality of monochromatic pixel sensor arrays 102a and 102c, and a full-color pixel sensor array 102b. The monochromatic pixel sensor array 102a, the monochromatic pixel sensor array 102c, and the full-color pixel sensor array 102b are independently controllable and are connected to independent control circuitry. This enables the monochromatic pixel sensor array 102a and the monochromatic pixel sensor array 102c to generate independent outputs based on incident light, and enables the full-color pixel sensor array 102b to generate independent outputs based on incident light.

As indicated above, FIGS. 5A-5C are provided as examples. Other examples may differ from what is described with regard to FIGS. 5A-5C.

FIGS. 6A-6H are diagrams of example implementations of a portion of a pixel sensor array 102b described herein. For example, each of FIGS. 6A-6H illustrates a cross-sectional view of an example implementation of a portion of the pixel sensor array 102b that may be included in the image sensor device 500, the image sensor device 508, and/or another image sensor device. The cross-sectional views illustrated in FIGS. 6A-6H are along the line B-B in FIGS. 5A and 5C.

FIG. 6A illustrates example implementation 600 of a portion of the pixel sensor array 102a that includes color pixel sensors 106, 502, and 504 (not shown). As shown in FIG. 6A, the example implementation 600 of a portion of the pixel sensor array 102b is similar to the example implementation 200 of a portion of the pixel sensor array 102 in FIG. 2A, except that color filters 230 are included over the photodiodes 204 for the color pixel sensor 106, 502, and 504, and the electrochromic layer stack 234 is included over the color filters 230. The color pixels sensors 106 may have a first type color filters 230 (e.g., red color filters), the color pixel sensors 502 may have a second type color filters 230 (e.g., green color filters), and the color pixel sensors 504 may have third type color filters 230 (e.g., blue color filters).

FIG. 6B illustrates another example implementation 602 of a portion of the pixel sensor array 102b that includes color pixel sensors 106, 502, and 504 (not shown). As shown in FIG. 6B, the example implementation 602 of a portion of the pixel sensor array 102b is similar to the example implementation 600 of a portion of the pixel sensor array 102b. However, in the example implementation 602, the layers of the electrochromic layer stack 234 are horizontally arranged as opposed to vertically arranged. Thus, the bottom transparent electrode 236 is laterally adjacent to the ion-storage layer 238, the electrolyte layer 240 is laterally adjacent the ion-storage layer 238, the electrochromic layer 242 is laterally adjacent to the electrolyte layer 240, and the top transparent electrode 244 is laterally adjacent to the electrochromic layer 242.

FIG. 6C illustrates another example implementation 604 of a portion of the pixel sensor array 102b that includes color pixel sensors 106, 502, and 504 (not shown). As shown in FIG. 6C, the example implementation 604 of a portion of the pixel sensor array 102b is similar to the example implementation 600 of a portion of the pixel sensor array 102b. However, in the example implementation 604, electrochromic layer stacks 234a, 234b are recessed in the isolation grid 224 above the photodiodes 204 of the color pixel sensors 106, 502, and 504 of the pixel sensor array 102b. Moreover, the color filters 230 of the color pixel sensors 106, 502, and 504 are integrated into the electrochromic layer stacks 234a, 234b.

FIG. 6D illustrates another example implementation 606 of a portion of the pixel sensor array 102b that includes color pixel sensors 106, 502, and 504 (not shown). As shown in FIG. 6D, the example implementation 606 of a portion of the pixel sensor array 102b is similar to the example implementation 600 of a portion of the pixel sensor array 102b in that electrochromic layer stacks 234a, 234b are recessed in the isolation grid 224 above the photodiodes 204 of the color pixel sensors 106, 502, and 504. However, in the example implementation 606, the layers of the electrochromic layer stack 234a, 234b are horizontally arranged as opposed to vertically arranged.

FIG. 6E illustrates another example implementation 608 of a portion of the pixel sensor array 102b that includes color pixel sensors 106, 502, and 504 (not shown). As shown in FIG. 6E, the example implementation 608 of a portion of the pixel sensor array 102b is similar to the example implementation 600 of a portion of the pixel sensor array 102b. However, in the example implementation 608, electrochromic layer stacks 234a, 234b are also recessed in the isolation grid 224 above the photodiodes 204 of the color pixel sensors 106, 502, and 504, in addition to an electrochromic layer stack 234c being included above the isolation grid 224 of the pixel sensor array 102b. The electrochromic layer stack 234c above the isolation grid 224, and the electrochromic layer stacks 234a, 234b recessed in the isolation grid 224, include layers that are stacked and vertically arranged in the z-direction in the image sensor device 100.

FIG. 6F illustrates another example implementation 610 of a portion of the pixel sensor array 102b that includes color pixel sensors 106, 502, and 504 (not shown). As shown in FIG. 6F, the example implementation 610 of a portion of the pixel sensor array 102b is similar to the example implementation 608 of a portion of the pixel sensor array 102b in that electrochromic layer stacks 234a, 234b are also recessed in the isolation grid 224 above the photodiodes 204 of the color pixel sensors 106, 502, and 504, in addition to an electrochromic layer stack 234c being included above the isolation grid 224 of the pixel sensor array 102b. However, in the example implementation 610, the layers of the electrochromic layer stacks 234a, 234b embedded in the isolation grid 224 for the color pixel sensors 106, 502, and 504 are horizontally arranged as opposed to being vertically arranged as in the example implementation 608.

FIG. 6G illustrates another example implementation 612 of a portion of the pixel sensor array 102b that includes color pixel sensors 106, 502, and 504 (not shown). As shown in FIG. 6G, the example implementation 612 of a portion of the pixel sensor array 102b is similar to the example implementation 608 of a portion of the pixel sensor array 102b in that electrochromic layer stacks 234a, 234b are also recessed in the isolation grid 224 above the photodiodes 204 of the color pixel sensors 106, 502, and 504, in addition to an electrochromic layer stack 234c being included above the isolation grid 224 of the pixel sensor array 102b. However, in the example implementation 612, the layers of the electrochromic layer stack 234c above the isolation grid 224 are horizontally arranged as opposed to being vertically arranged as in the example implementation 608.

FIG. 6H illustrates another example implementation 614 of a portion of the pixel sensor array 102b that includes color pixel sensors 106, 502, and 504 (not shown). As shown in FIG. 6H, the example implementation 614 of a portion of the pixel sensor array 102b is similar to the example implementation 608 of a portion of the pixel sensor array 102b in that electrochromic layer stacks 234a, 234b are also recessed in the isolation grid 224 above the photodiodes 204 of the color pixel sensors 106, 502, and 504, in addition to an electrochromic layer stack 234c being included above the isolation grid 224 of the pixel sensor array 102. However, in the example implementation 614, the layers of the electrochromic layer stack 234c above the isolation grid 224 are horizontally arranged as opposed to being vertically arranged as in the example implementation 608. Moreover, the layers of the electrochromic layer stacks 234a, 234b embedded in the isolation grid 224 for the color pixel sensors 106, 502, and 504 are also horizontally arranged as opposed to being vertically arranged as in the example implementation 608.

As indicated above, FIGS. 6A-6H are provided as examples. Other examples may differ from what is described with regard to FIGS. 6A-6H.

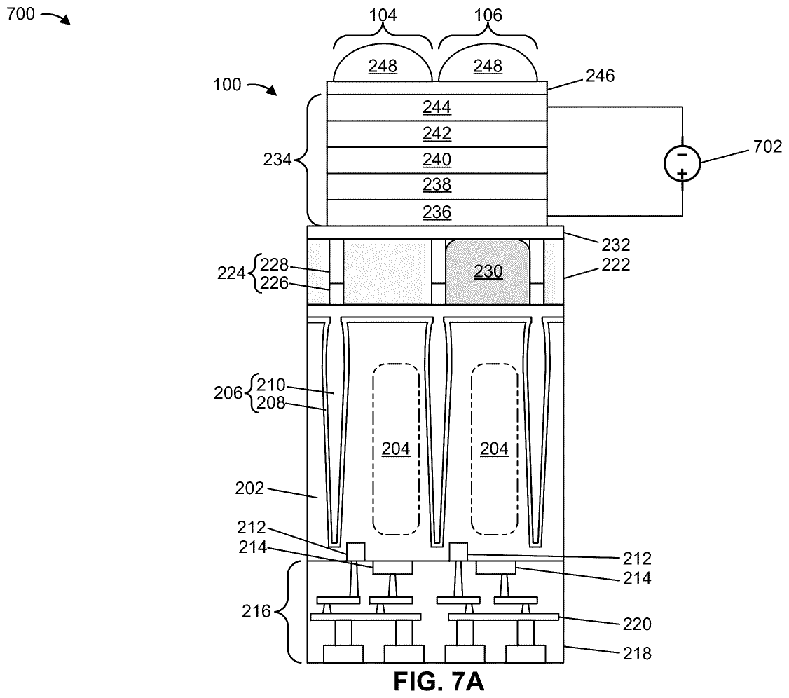

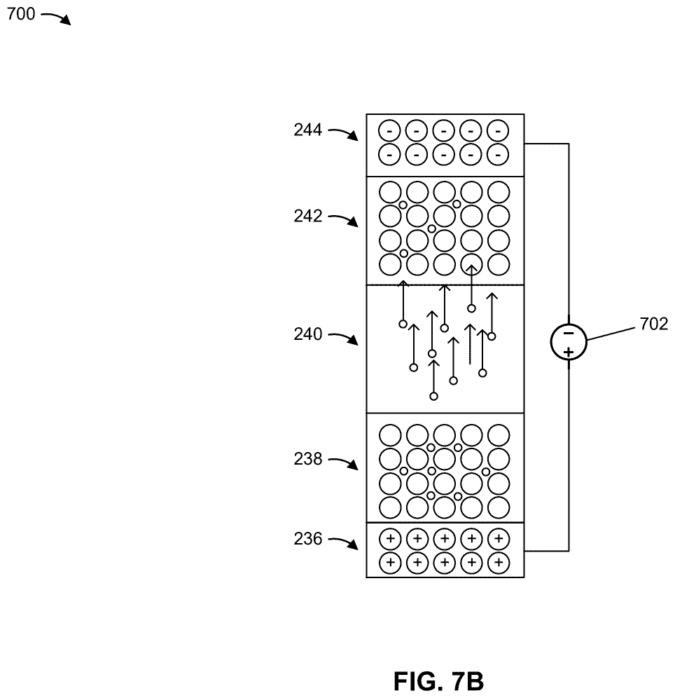

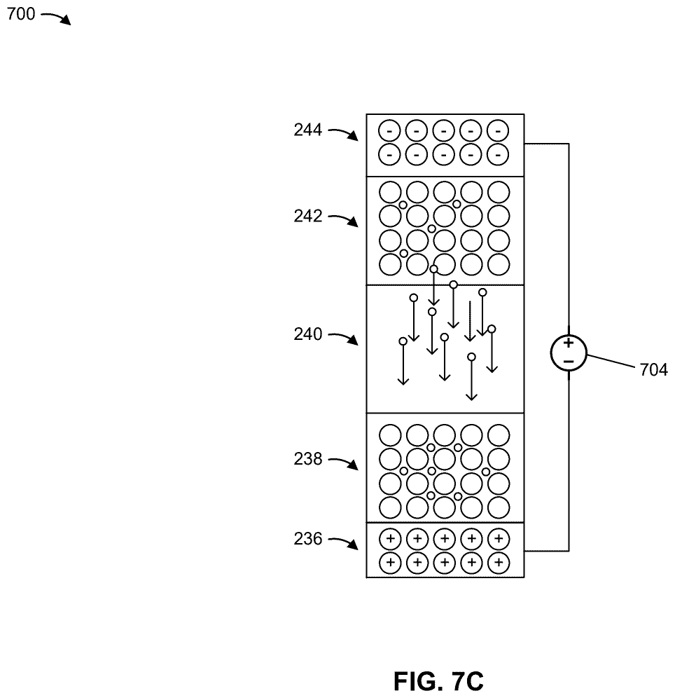

FIGS. 7A-7C are diagrams of an example implementation 700 of adjusting an optical transmittance of an electrochromic layer stack 234 described herein. As shown in FIG. 7A, an electrical input 702 (e.g., a voltage, a current) may be applied to the bottom transparent electrode 236 and to the top transparent electrode 244. As shown in FIG. 7B, the electrical input 702 causes ions from the ion-storage layer 238 to be transported to the electrochromic layer 242 through the electrolyte layer 240. The ions are retained in the electrochromic layer 242, thereby reducing the transparency of the electrochromic layer 242, which reduces the optical transmittance of the electrochromic layer 242. As shown in FIG. 7C, another electrical input 704 (e.g., a reversed polarity electrical input) causes ions from the electrochromic layer 242 to be transported from the electrochromic layer 242 to the ion-storage layer 238 through the electrolyte layer 240. Ions are thus removed from the electrochromic layer 242, thereby increasing the transparency of the electrochromic layer 242, which increases the optical transmittance of the electrochromic layer 242.

As indicated above, FIGS. 7A-7C are provided as an example. Other examples may differ from what is described with regard to FIGS. 7A-7C.

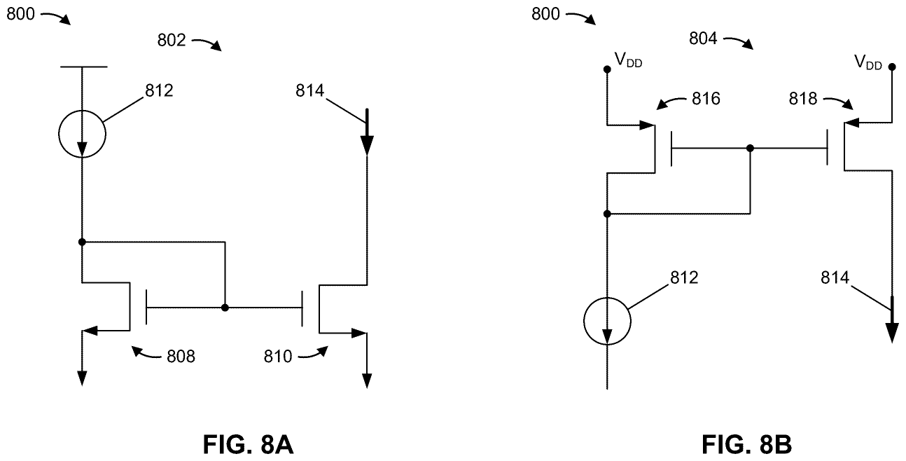

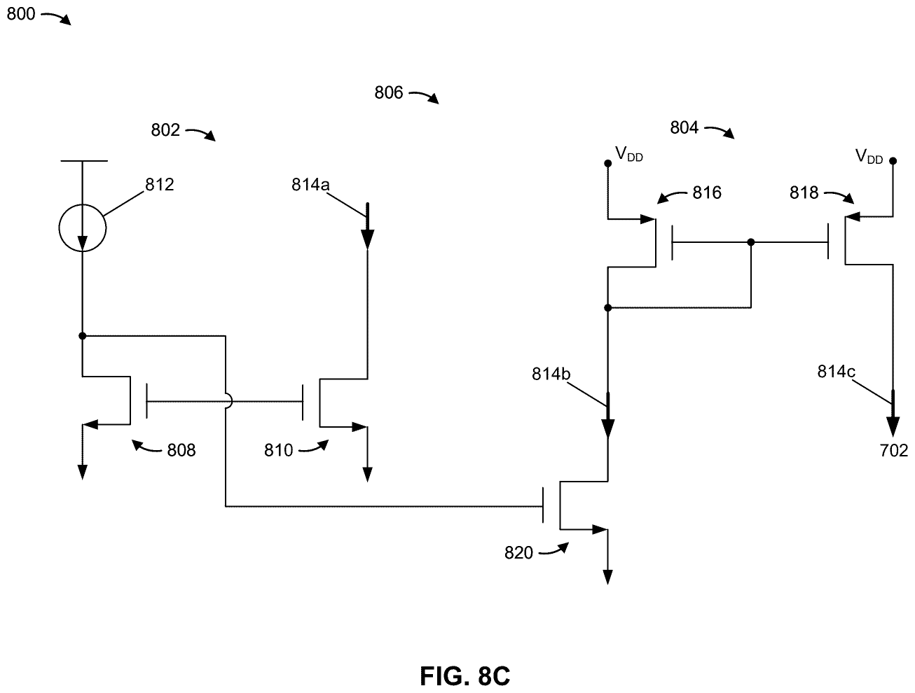

FIGS. 8A-8C are diagrams of an example implementation 800 of a constant current source or portions thereof described herein. The constant current source illustrated and described in connection with FIGS. 8A-8C may be used to provide electrical inputs to an electrochromic layer stack 234 described herein. The constant current source illustrated and described in connection with FIGS. 8A-8C enables a constant supply current (or near-constant supply current) to be provided to the electrochromic layer stack 234, particularly in the case of battery-operated devices in which the supply voltage may drop over time as the batter drains. This enables the operation of the electrochromic layer stack 234 to be stabilized and enables the operational lifetime of the electrochromic layer stack 234 to be extended.

FIG. 8A illustrates an n-type metal-oxide-semiconductor (NMOS) current mirror circuit 802 of the constant current source. FIG. 8B illustrates a p-type metal-oxide-semiconductor (PMOS) current mirror circuit 804 of the constant current source. FIG. 8C illustrates the constant current source 806, including the NMOS current mirror circuit 802 and the PMOS current mirror circuit 804. The NMOS current mirror circuit 802 and the PMOS current mirror circuit 804 may enable the constant supply current generated by the constant current source 806 to be consistently and equally mirrored or copied across electrochromic layer stacks 234.

As shown in FIG. 8A, the NMOS current mirror circuit 802 includes a plurality of metal-oxide-semiconductor field effect transistors (MOSFETs) 808 and 810, which are NMOS transistors. The MOSFETs 808 and 810 are gate connected, and the gates of the MOSFETs 808 and 810 are also connected to the drain of the MOSFET 808. The drain of the MOSFET 808 is connected to a reference current source (I_{REF}) 812, and a mirrored current (I_{D}) 810 is provided from the drain to the source of the MOSFET 810. The drain-source voltage (V_{ds}) of the MOSFETs 808 and 810 is greater than the gate-source voltage (V_{gs}) applied to the MOSFETs 808 and 810 minus the threshold voltage (Vₜ) of the MOSFETs 808 and 810 (e.g., V_{ds}>V_{gs}−Vₜ), which causes the MOSFETs 808 and 810 to operate in saturation mode.

If the MOSFETs 808 and 810 are matched transistors, the reference current source (I_{REF}) 812 and the mirrored current (I_{D}) 814 are approximately equal. In other words:

$${I}_{D} = \frac{{I}_{R E F} \times ( \frac{{W}_{{I}_{D}}}{{L}_{{I}_{D}}} )}{( \frac{{W}_{R E F}}{{L}_{R E F}} )}$$

where W_{REF} is the width of the MOSFET 808, L_{REF} is the length of the MOSFET 808, W_{I}_{_{D}} is the width of the MOSFET 810, L_{I}_{_{D}} is the length of the MOSFET 810. If

$$\frac{{W}_{{I}_{D}}}{{L}_{{I}_{D}}} and \frac{{W}_{R E F}}{{L}_{R E F}}$$

are approximately equal, the MOSFETs 808 and 810 are matched, and the mirrored current (I_{D}) 814 is approximately equal to the reference current source (I_{REF}) 812. This enables the reference current source (I_{REF}) 812 to be mirrored or copied from the MOSFET 808 to the MOSFET 810.

As shown in FIG. 8B, the PMOS current mirror circuit 804 includes a plurality of MOSFETs 816 and 818, which are PMOS transistors. The MOSFETs 816 and 818 are gate connected, and the gates of the MOSFETs 816 and 818 are also connected to the drain of the MOSFET 816. The source of the MOSFET 816 is connected to a drain-drain voltage (V_{DD}) such that a reference current source (I_{REF}) 812 flows from the source to the drain of the MOSFET 816. A mirrored current (I_{D}) 814 may be provided from the source to the drain of the MOSFET 818. The drain-drain voltage (V_{DD}) and the source-gain voltage (V_{sg}) are equal for the MOSFETs 808 and 810. If the MOSFETs 816 and 818 are matched transistors, as described above, the reference current source (I_{REF}) 812 and the mirrored current (I_{D}) 814 are approximately equal.

As shown in FIG. 8C, the NMOS current mirror circuit 802 and the PMOS current mirror circuit 804 may be coupled by a MOSFET 820. This enables the reference current source (I_{REF}) 812 to be mirrored across a plurality of MOSFETs, including the MOSFET 810 (mirrored current (I_{D}) 814a), the MOSFETs 816 and 820 (mirrored current (I_{D}) 814b), and/or the MOSFET 818 (mirrored current (I_{D}) 814c), among other examples. In some implementations, the mirrored current (I_{D}) 814c may be provided as an electrical input 702 to an electrochromic layer stack 234.

As indicated above, FIGS. 8A-8C are provided as an example. Other examples may differ from what is described with regard to FIGS. 8A-8C.

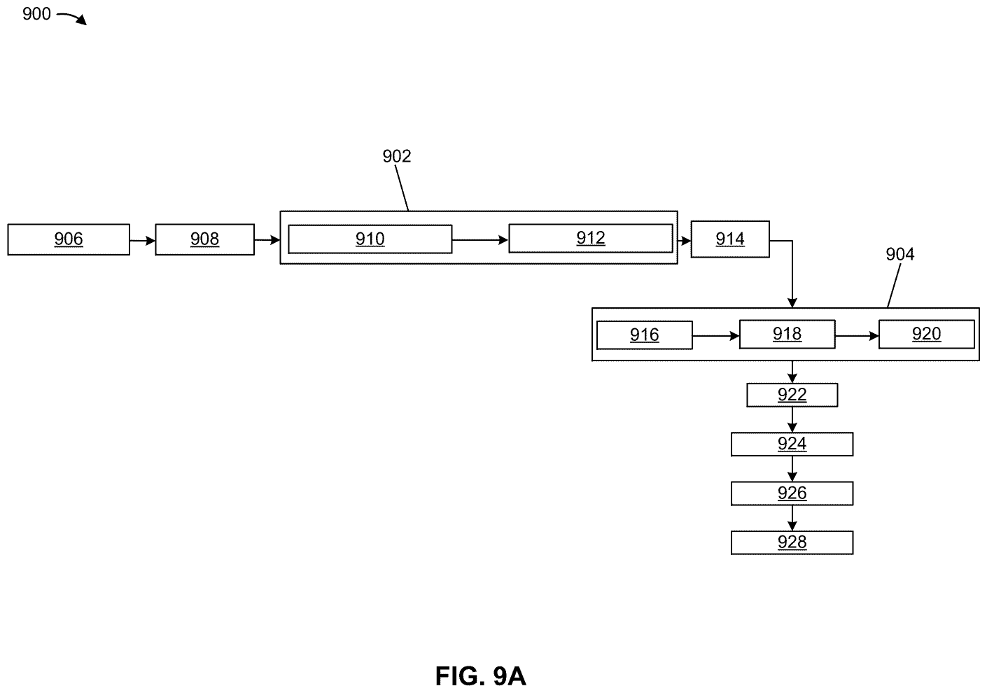

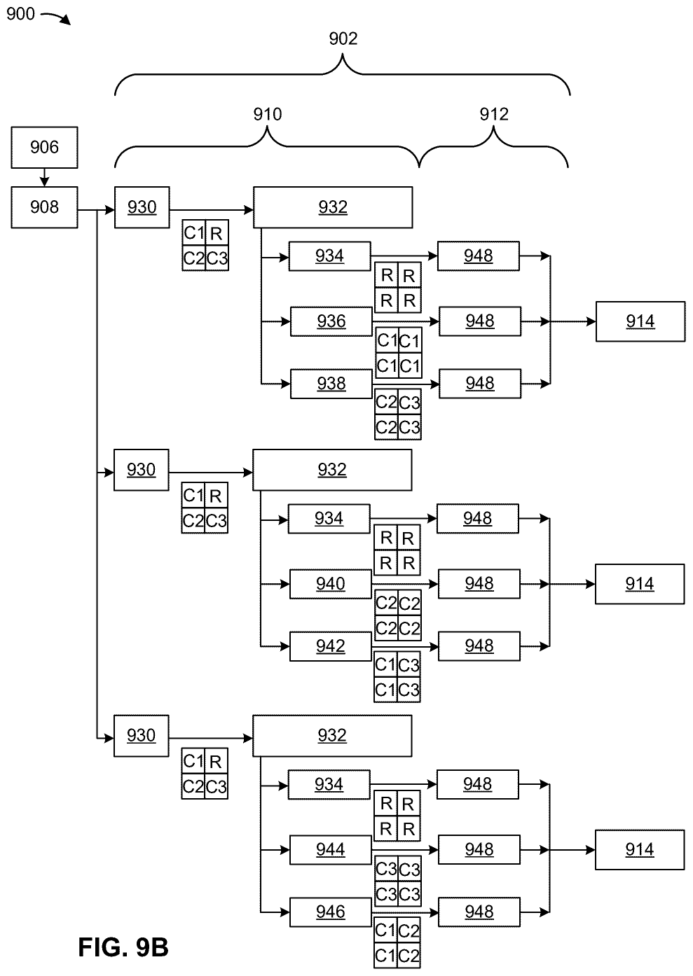

FIGS. 9A and 9B are diagrams of an example implementation 900 of a compression circuit 902 and a decompression circuit 904 that may be communicatively (e.g., electrically, optically) coupled to one or more of the pixel sensor arrays described herein. For example, the compression circuit 902 and the decompression circuit 904 may be communicatively coupled to an image sensor device 906 (e.g., an image sensor device 100, an image sensor device 500, an image sensor device 506, an image sensor device 508) that includes a monochromatic pixel sensor array 102, 102a, and/or 102c, and/or to a full-color pixel sensor array 102b, among other examples. The compression circuit 902 and the decompression circuit 904 may be integrated into the image sensor device, may be included in a standalone compression/decompression device, and/or may be integrated into another semiconductor device.

Turning to FIG. 9A, the image sensor device 906 may provide an input image 908 (or input video) to the compression circuit 902. The compression circuit 902 (e.g., an image data compression circuit) may compress the input image 908 in an efficient and highly parallelized manner compared to other compression techniques such as piecewise linear compression. To parallelize the compression of the input image 908, the compression circuit 902 includes a pre-processing circuit 910 that decomposes the input image 908 into sub-images in parallel, and an encoding circuit 912 that compresses and maps the data of the sub-images in parallel to an image container 914.

Similarly, the decompression circuit 904 (e.g., an image data decompression circuit) may decompress the stored image in the image container 914 in an efficient and highly parallelized manner. The decompression circuit 904 may include a decoding circuit 916, an inverse mapping circuit 918, and a post-processing circuit 920 that converts the compressed data of the storage image in the image container 914 back to the raw data of the input image 908. The raw data may be provided to down-stream processing circuits, such as an image signal processor (ISP) circuit 922, an output circuit 924, an image correction circuit 926, and/or a user application circuit 928.

FIG. 9B illustrates a detailed example of a compression operation performed by the compression circuit 902 for a red monochromatic image generated by a monochromatic pixel sensor array 102, 102a, and/or 102c of the image sensor device 906. However, the operations described in connection with FIG. 9B may be performed for other types of monochromatic images.

As shown in FIG. 9B, the input image 908 is provided to the pre-processing circuit 910, which performs parallel decomposition operations 930 to decompose the input image 908 into four (4) image components: an R component (red component), a C1 component (first white/clear component), a C2 component (second white/clear component), and a C3 component (third white/clear component). The R component is generated from the color pixel sensors 106 of the monochromatic pixel sensor array, the C1 component, the C2 component, and the C₃ component are generated from the white pixel sensors 104 of the monochromatic pixel sensor array. Each of the components corresponds to one quarter (¼^{th}) of the original resolution of the input image 908.

As further shown in FIG. 9B, parallel interpolation operations 932 are performed by the pre-processing circuit 910, which generates additional interpolated components from the C1 component, the C2 component, and the C₃ component. The output from the interpolation operation 932 includes the R component 934, the C1 component 936, a C2C3 component 938, the C2 component 940, a C1C3 component 942, the C3 component 944, and a C1C2 component 946. The components 934-946 are provided to the encoding circuit 912, which performs parallel compression operations 948 to map and compress the components 934-946. The compressed components 934-946 are then stored in the image container 914.

As indicated above, FIGS. 9A and 9B are provided as an example. Other examples may differ from what is described with regard to FIGS. 9A and 9B.

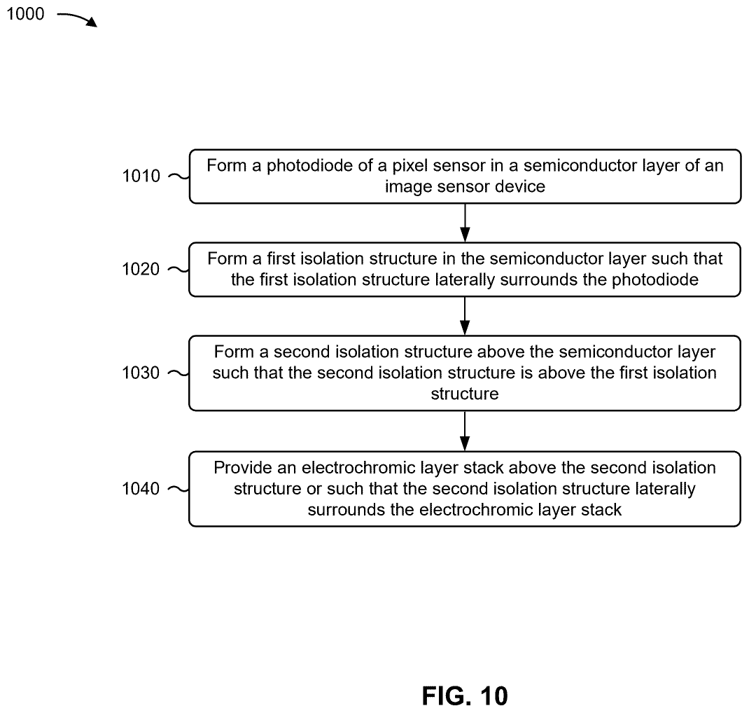

FIG. 10 is a flowchart of an example process 1000 associated with forming an image sensor device described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming a photodiode (204) of a pixel sensor in a semiconductor layer of an image sensor device (block 1010). For example, one or more semiconductor processing tools may be used to form a photodiode (e.g., a photodiode 204) of a pixel sensor (e.g., a color pixel sensor 106, a color pixel sensor 502, a color pixel sensor 504) in a semiconductor layer (e.g., a substrate 202) of an image sensor device (e.g., an image sensor device 100, an image sensor device 500), as described herein.

As further shown in FIG. 10, process 1000 may include forming a first isolation structure in the semiconductor layer such that the first isolation structure laterally surrounds the photodiode (block 1020). For example, one or more semiconductor processing tools may be used to form a first isolation structure (e.g., an isolation structure 206) in the semiconductor layer such that the first isolation structure laterally surrounds the photodiode, as described herein.

As further shown in FIG. 10, process 1000 may include forming a second isolation structure above the semiconductor layer such that the second isolation structure is above the first isolation structure (block 1030). For example, one or more semiconductor processing tools may be used to form a second isolation structure (e.g., an isolation grid 224) above the semiconductor layer such that the second isolation structure is above the first isolation structure, as described herein.

As further shown in FIG. 10, process 1000 may include providing an electrochromic layer stack (234) above the second isolation structure or such that the second isolation structure laterally surrounds the electrochromic layer stack (block 1040). For example, one or more semiconductor processing tools may be used to provide an electrochromic layer stack (e.g., an electrochromic layer stack 234) above the second isolation structure or such that the second isolation structure laterally surrounds the electrochromic layer stack, as described herein.

Process 1000 may include additional implementations, such as any single implementation or any combination of implementations described below and/or in connection with one or more other processes described elsewhere herein.

In a first implementation, process 1000 may include forming a color filter (e.g., a color filter 230) layer above the photodiode such that the second isolation structure laterally surrounds the color filter layer.

In a second implementation, alone or in combination with the first implementation, providing the electrochromic layer stack includes forming a bottom transparent electrode (e.g., a transparent electrode 236) above the color filter, providing an ion-storage layer (e.g., an ion-storage layer 238) above the bottom transparent electrode, forming an electrolyte layer (e.g., an electrolyte layer 240) above the ion-storage layer, providing an electrochromic layer (e.g., an electrochromic layer 242) above the electrolyte layer, and providing a top transparent electrode (e.g., a top transparent electrode 244) above the electrochromic layer.

In a third implementation, alone or in combination with one or more of the first and second implementations, providing the electrochromic layer stack includes providing the electrochromic layer stack such that an electrochromic layer in the electrochromic layer stack has an octahedral crystal structure (e.g., a crystal structure 404).

In a fourth implementation, alone or in combination with one or more of the first through third implementations, the electrochromic layer includes tungsten oxide (WO₆).

In a fifth implementation, alone or in combination with one or more of the first through fourth implementations, providing the electrochromic layer stack includes providing the electrochromic layer stack such that the color filter is included in the electrochromic layer stack.

In a sixth implementation, alone or in combination with one or more of the first through fifth implementations, process 1000 includes providing another electrochromic layer stack (e.g., another electrochromic layer stack 234) above the second isolation structure.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, an image sensor device includes a pixel sensor array and an electrochromic layer stack over the pixel sensor array. An electrical input may be applied to the electrochromic layer stack to adjust the intensity of incident light received at the pixel sensors of the pixel sensor array. In this way, the electrochromic layer stack enables the intensity of incident light received at the pixel sensors of the pixel sensor array to be adjusted to a suitable level for the level of illuminance in the surrounding environment, and enables the intensity of incident light received at the pixel sensors of the pixel sensor array to be adapted to changes in the level of illuminance in the surrounding environment.

As described in greater detail above, some implementations described herein provide an image sensor device. The image sensor device includes a pixel sensor array. The pixel sensor array includes a first plurality of pixel sensors, and includes a second plurality of pixel sensors that each include a color filter. The image sensor device also includes an electrochromic layer stack over the first plurality of pixel sensors and the second plurality of pixel sensors.

As described in greater detail above, some implementations described herein provide an image sensor device. The image sensor device includes a first pixel sensor array and a second pixel sensor array. The first pixel sensor array includes a first plurality, and includes a second plurality of pixel sensors that each include a color filter associated with a first wavelength range of visible light. The second pixel sensor array includes a third plurality of pixel sensors that each include a color filter associated with the first wavelength range of visible light, and a fourth plurality of pixel sensors that each include a color filter associated with a second wavelength range of visible light that is different from the first wavelength range. The image sensor device further includes a first electrochromic layer stack over the first plurality of pixel sensors and the second plurality of pixel sensors. The image sensor device further includes a second electrochromic layer stack over the third plurality of pixel sensors and the fourth plurality of pixel sensors.

As described in greater detail above, some implementations described herein provide a method. The method includes forming a photodiode of a pixel sensor in a semiconductor layer of an image sensor device. The method includes forming a first isolation structure in the semiconductor layer such that the first isolation structure laterally surrounds the photodiode. The method includes forming a second isolation structure above the semiconductor layer such that the second isolation structure is above the first isolation structure. The method includes forming an electrochromic layer stack above the second isolation structure or such that the second isolation structure laterally surrounds the electrochromic layer stack.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor device, comprising:
a pixel sensor array, comprising:
a first plurality of pixel sensors; and
a second plurality of pixel sensors each comprising a color filter; and
an electrochromic layer stack over the first plurality of pixel sensors and the second plurality of pixel sensors.

2. The image sensor device of claim 1, wherein the color filters of the second plurality of pixel sensors are associated with a same wavelength range of visible light.

3. The image sensor device of claim 1, wherein the electrochromic layer stack comprises an electrochromic layer, an electrolyte layer, and an ion-storage layer that are included between transparent electrodes of the electrochromic layer stack; and
wherein the electrochromic layer, the electrolyte layer, the ion-storage layer, and the transparent electrodes are vertically arranged in the image sensor device.

4. The image sensor device of claim 1, wherein the electrochromic layer stack is above the color filters of the second plurality of pixel sensors.

5. The image sensor device of claim 1, wherein the electrochromic layer stack comprises a electrochromic layer, an electrolyte layer, and an ion-storage layer that are included between transparent electrodes of the electrochromic layer stack; and
wherein the electrochromic layer, the electrolyte layer, the ion-storage layer, and the transparent electrodes are horizontally arranged in the image sensor device.

6. The image sensor device of claim 1, wherein the electrochromic layer stack is a first electrochromic layer stack of the image sensor device; and
wherein the image sensor device further comprises:
a second electrochromic layer stack between the first electrochromic layer stack and a photodiode of a pixel sensor of the second plurality of pixel sensors.

7. The image sensor device of claim 6, wherein an electrochromic layer of the second electrochromic layer stack corresponds to the color filter of the pixel sensor.

8. An image sensor device, comprising:
a first pixel sensor array, comprising:
a first plurality of pixel sensors; and
a second plurality of pixel sensors each comprising a color filter associated with a first wavelength range of visible light;
a first electrochromic layer stack over the first plurality of pixel sensors and the second plurality of pixel sensors;
a second pixel sensor array, comprising:
a third plurality of pixel sensors each comprising a color filter associated with the first wavelength range of visible light; and
a fourth plurality of pixel sensors each comprising a color filter associated with a second wavelength range of visible light that is different from the first wavelength range; and
a second electrochromic layer stack over the third plurality of pixel sensors and the fourth plurality of pixel sensors.

9. The image sensor device of claim 8, wherein the first electrochromic layer stack is electrically coupled to a constant current source.

10. The image sensor device of claim 9, wherein the constant current source comprises one or more current mirror circuits.

11. The image sensor device of claim 10, wherein the one or more current mirror circuits comprise a n-type metal-oxide-semiconductor (NMOS) current mirror circuit.

12. The image sensor device of claim 11, wherein the one or more current mirror circuits comprise a p-type metal-oxide-semiconductor (PMOS) current mirror circuit electrically coupled to the NMOS current mirror circuit.

13. The image sensor device of claim 8, wherein the image sensor device further comprises:
an image data compression circuit coupled to the first pixel sensor array.

14. The image sensor device of claim 13, wherein the image sensor device further comprises:
an image data decompression circuit coupled to the first pixel sensor array.

15. A method, comprising:
forming a photodiode of a pixel sensor in a semiconductor layer of an image sensor device;
forming a first isolation structure in the semiconductor layer such that the first isolation structure laterally surrounds the photodiode;
forming a second isolation structure above the semiconductor layer such that the second isolation structure is above the first isolation structure; and
providing an electrochromic layer stack above the second isolation structure or such that the second isolation structure laterally surrounds the electrochromic layer stack.

16. The method of claim 15, further comprising:
providing a color filter above the photodiode such that the second isolation structure laterally surrounds the color filter.

17. The method of claim 15, wherein providing the electrochromic layer stack comprises:
providing a bottom transparent electrode above the color filter;
providing an ion-storage layer above the bottom transparent electrode;
providing an electrolyte layer above the ion-storage layer;
providing an electrochromic layer above the electrolyte layer; and
providing a top transparent electrode above the electrochromic layer.

18. The method of claim 17, wherein providing the electrochromic layer stack comprises:
providing the electrochromic layer stack such that an electrochromic layer in the electrochromic layer stack has an octahedral crystal structure.

19. The method of claim 17, wherein the electrochromic layer comprises tungsten oxide (WO₆).

20. The method of claim 16, wherein providing the electrochromic layer stack comprises:
providing the electrochromic layer stack such that the color filter is included in the electrochromic layer stack.
